(19) United States
(12) Patent Application Publication
(10) Pub. No.: US 2026/0173521 A1
(43) Pub. Date: Jun. 18, 2026

(54) SEMICONDUCTOR DEVICE

(71) Applicant: Samsung Electronics Co., Ltd., Suwon-si (KR)

(72) Inventors: Hyunho Noh, Suwon-si (KR); Jeonghyuk Yim, Suwon-si (KR); Youbin Kim, Suwon-si (KR); Inhak Lee, Suwon-si (KR); Chanhyeong Lee, Suwon-si (KR); Jinkyu Jang, Suwon-si (KR)

(21) Appl. No.: 19/238,682

(22) Filed: Jun. 16, 2025

(30) Foreign Application Priority Data
Dec. 17, 2024 (KR) 10-2024-0188702

(51) Int. Cl. H10D 84/90; H10D 89/10

(52) U.S. Cl. CPC H10D 84/964; H10D 84/953; H10D 89/10

(57) ABSTRACT

A semiconductor device includes a substrate including an active pattern, and a channel pattern on the active pattern. The channel pattern includes a plurality of semiconductor patterns that are stacked and are spaced apart from each other, a source/drain pattern connected to the plurality of semiconductor patterns, and a gate electrode on the plurality of semiconductor patterns. The gate electrode includes respective parts that are between adjacent semiconductor patterns among the plurality of semiconductor patterns, and an uppermost part on an uppermost semiconductor pattern. The uppermost part includes a first metal pattern, a second metal pattern on the first metal pattern, a filling metal pattern on the second metal pattern, and a metal liner pattern between the first metal pattern and the second metal pattern. The metal liner pattern includes at least one selected from the group consisting of Ti, Ta, Nb, Al, W and Mo.

### CROSS-REFERENCE TO RELATED APPLICATIONS

This U.S. non-provisional patent application claims priority under 35 U.S.C. § 119 of Korean Patent Application No. 10-2024-0188702, filed on Dec. 17, 2024, the entire contents of which are hereby incorporated by reference.

### TECHNICAL FIELD

The present disclosure herein relates to a semiconductor device, and more particularly, to a semiconductor device including a field effect transistor.

### BACKGROUND

A semiconductor device may include an integrated circuit composed of metal-oxide-semiconductor field effect transistors (MOSFETs). As a size and a design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may be deteriorated. Accordingly, research on various methods for overcoming limitations caused by high-integration of the semiconductor device and forming the semiconductor device with improved performance is being conducted.

### SUMMARY

The present disclosure provides a semiconductor device with improved reliability and electrical characteristics.

The inventive concept is not limited to aspects mentioned herein, and other aspects that are not mentioned may be clearly understood from description below by those skilled in the art.

An embodiment of the inventive concept provides a semiconductor device including a substrate including an active pattern, a channel pattern on the active pattern, wherein the channel pattern includes a plurality of semiconductor patterns that are stacked and spaced apart from each other, a source/drain pattern connected to the plurality of semiconductor patterns, and a gate electrode on the plurality of semiconductor patterns, wherein the gate electrode includes respective parts between adjacent semiconductor patterns among the plurality of semiconductor patterns, and an uppermost part on an uppermost semiconductor pattern among the plurality of semiconductor patterns, wherein the uppermost part includes a first metal pattern, a second metal pattern on the first metal pattern, a filling metal pattern on the second metal pattern, and a metal liner pattern between the first metal pattern and the second metal pattern, and the metal liner pattern includes at least one selected from the group consisting of Ti, Ta, Nb, Al, W, and Mo.

In an embodiment of the inventive concept, a semiconductor device includes a substrate including a PMOSFET region, an active pattern on the PMOSFET region, a channel pattern on the active pattern and including a plurality of semiconductor patterns that are stacked and spaced apart from each other, a source/drain pattern connected to the plurality of semiconductor patterns, a gate electrode on the plurality of semiconductor patterns and including respective inner electrodes between adjacent semiconductor patterns among the plurality of semiconductor patterns, and an outer electrode on an uppermost semiconductor pattern among the plurality of semiconductor patterns, a gate insulating layer between the gate electrode and the semiconductor patterns adjacent to each other, and an active contact electrically connected to the source/drain pattern, wherein the outer electrode includes a first metal pattern and a metal filling layer on the first metal pattern, and the metal filling layer extends between inner sidewalls of the gate insulating layer and between inner sidewalls of the first metal pattern.

In an embodiment of the inventive concept, a semiconductor device includes a first active pattern on a first active region of a substrate, and a second active pattern on a second active region of the substrate, an element separation layer in a trench between the first and second active patterns, a first channel pattern on the first active pattern and including first semiconductor patterns that are stacked and spaced apart from each other, a second channel pattern on the second active pattern and including second semiconductor patterns that are stacked and spaced apart from each other, a first gate electrode on the first channel pattern, a second gate electrode on the second channel pattern, a first interlayered insulating layer on the first and second gate electrodes, gate contacts penetrating the first interlayered insulating layer and connected to the first and second gate electrodes, a second interlayered insulating layer on the first interlayered insulating layer, a first metal layer in the second interlayered insulating layer, and wherein the first metal layer includes first wires electrically connected to the gate contacts, a third interlayered insulating layer on the second interlayered insulating layer, and a second metal layer in the third interlayered insulating layer, wherein the second metal layer includes second wires electrically connected to the first wires, the first gate electrode includes respective first inner electrodes in inner regions between the first semiconductor patterns, and a first outer electrode on an uppermost first semiconductor pattern among the first semiconductor patterns, the second gate electrode includes respective second inner electrodes in inner regions between the second semiconductor patterns, and a second outer electrode on an uppermost second semiconductor pattern among the second semiconductor patterns, the first outer electrode includes a first metal pattern, and a filling metal pattern on the first metal pattern, the second outer electrode includes a second metal pattern, a third metal pattern on the second metal pattern, a metal liner pattern interposed between the second and third metal patterns, and the filling metal pattern on the third metal pattern, and the metal liner pattern includes tungsten (W), and has a substantially uniform thickness.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIGS. 1, 2, and 3 are conceptual or schematic diagrams for describing logic cells of a semiconductor device according to embodiments of the inventive concept;

FIG. 4 is a plan view for describing a semiconductor device according to embodiments of the inventive concept;

FIGS. 5A, 5B, 5C, and 5D are cross-sectional views taken along line A-A′, line B-B′, line C-C′ and line D-D′ of FIG. 4, respectively;

FIG. 6A is an enlarged diagram of region M of FIG. 5A;

FIG. 6B is an enlarged diagram of region N of FIG. 5B;

FIG. 6C is an enlarged diagram illustrating another embodiment of region N of FIG. 5B;

FIG. 6D is an enlarged diagram of region O of FIG. 5D;

FIG. 6E is an enlarged diagram of region P of FIG. 5D;

FIGS. 7A, 7B, 8A, 8B, 9A, 9B, 9C, 10A, 10B, 10C, 11A,11B, 11C, 11D, 12A, 12B, 12C, and 12D are cross-sectional views for describing a method for manufacturing a semiconductor device according to embodiments of the inventive concept; and

FIGS. 13A, 13B, 14A, 14B, 15A, 15B, 16A, 16B, 17A, 17B, 18A, and 18B are enlarged diagrams for describing a method for forming an outer electrode among gate electrodes, and illustrating region M of FIG. 5A and region N of FIG. 5B.

### DETAILED DESCRIPTION OF EMBODIMENTS

Hereinafter, embodiments according to the inventive concept will be described in more detail with reference to the accompanying drawings in order to more specifically describe the inventive concept. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. The terms “substantially” may be used herein to denote approximation or variation in characteristics of elements or layers described herein (e.g., within about 5 percent of the described characteristics), for example, due manufacturing tolerances.

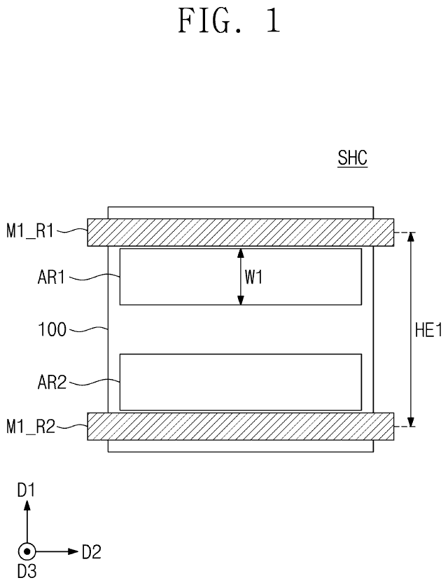

FIGS. 1 to 3 are conceptual or schematic diagrams for describing logic cells of a semiconductor device according to embodiments of the inventive concept.

Referring to FIG. 1, a single height cell SHC may be provided. Specifically, a first power wire M1_R1 and a second power wire M1_R2 may be provided on a substrate 100. The first power wire M1_R1 may be a path through which a source voltage VSS, for example, a ground voltage is provided. The second power wire M1_R2 may be a path through which a drain voltage VDD, for example, a power voltage is provided.

The single height cell SHC may be defined between the first power wire M1_R1 and the second power wire M1_R2. The single height cell SHC may include one first active region AR1 and one second active region AR2. Any one of the first and second active regions AR1 and AR2 may be a PMOSFET region, and the other one of the first and second active regions AR1 and AR2 may be an NMOSFET region. In other words, the single height cell SHC may have a structure in which a CMOS is provided between the first power wire M1_R1 and the second power wire M1_R2.

Each of the first and second active regions AR1 and AR2 may have a horizontal width W1 in a first direction D1. A length of the single height cell SHC in the first direction D1 may be defined as a vertical height HE1. The vertical height HE1 may be substantially the same as a distance (for example, a pitch) between the first power wire M1_R1 and the second power wire M1_R2.

The single height cell SHC may constitute one logic cell. In the present specification, the logic cell may mean a logic device (for example, AND, OR, XOR, XNOR, an inverter, or the like) that performs a specific function. That is, the logic cell may include transistors constituting the logic device, and wires connecting the transistors to each other.

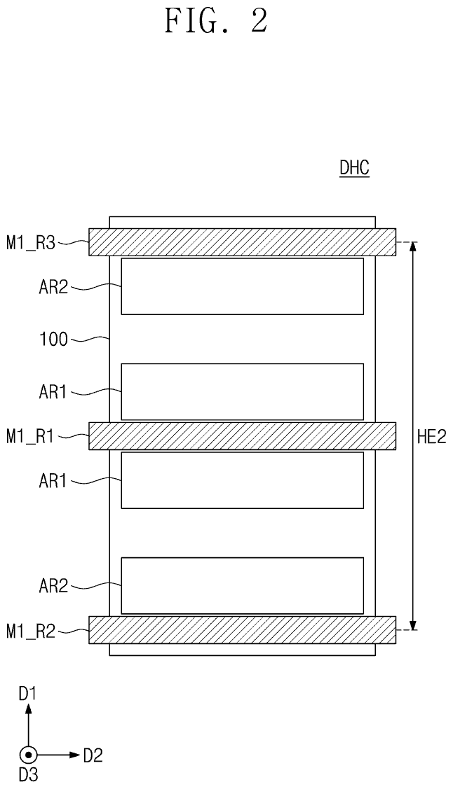

Referring to FIG. 2, a double height cell DHC may be provided. Specifically, the first power wire M1_R1, the second power wire M1_R2 and a third power wire M1_R3 may be provided on the substrate 100. The first power wire M1_R1 may be disposed between the second power wire M1_R2 and the third power wire M1_R3. The third power wire M1_R3 may be a path through which the source voltage VSS is provided.

The double height cell DHC may be defined between the second power wire M1_R2 and the third power wire M1_R3. The double height cell DHC may include two first active regions AR1 and two second active regions AR2.

One of the two second active regions AR2 may be adjacent to the second power wire M1_R2. The other one of the two second active regions AR2 may be adjacent to the third power wire M1_R3. The two first active regions AR1 may be adjacent to the first power wire M1_R1. On or in a plan view, the first power wire M1_R1 may be disposed between the two first active regions AR1.

A length of the double height cell DHC in the first direction D1 may be defined as a second vertical height HE2. The second vertical height HE2 may be longer than (e.g., about twice as long as) the vertical height HE1 of FIG. 1. The two first active regions AR1 of the double height cell DHC may operate together as one active region.

According to the inventive concept, the double height cell DHC illustrated in FIG. 2 may be defined as a multi-height cell. Although not shown, the multi-height cell may include a triple height cell of which a cell height is about three times longer than that of the single height cell SHC.

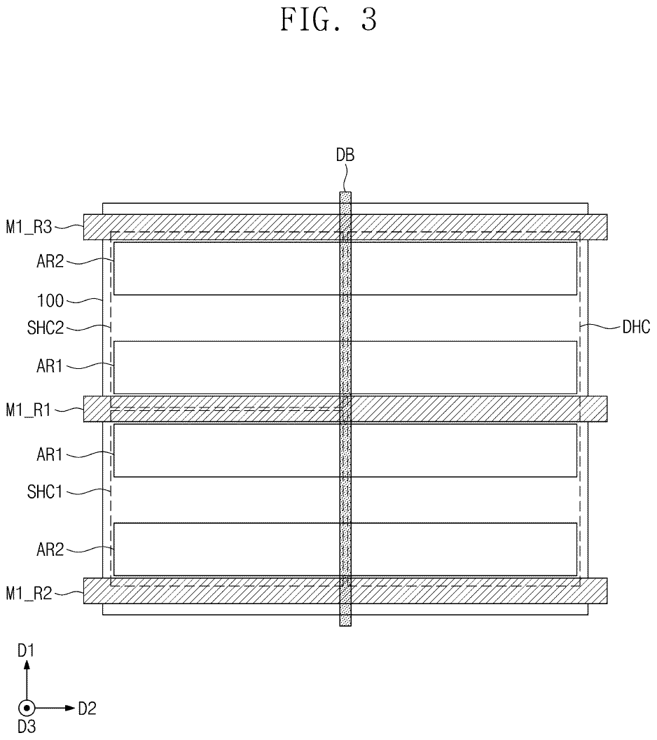

Referring to FIG. 3, a first single height cell SHC1, a second single height cell SHC2, and the double height cell DHC may be two-dimensionally disposed on the substrate 100. The first single height cell SHC1 may be disposed between the first and second power wires M1_R1 and M1_R2. The second single height cell SHC2 may be disposed between the first and third power wires M1_R1 and M1_R3. The second single height cell SHC2 may be adjacent to the first single height cell SHC1 in the first direction D1.

The double height cell DHC may be disposed between the second and third power wires M1_R2 and M1_R3. The double height cell DHC may be adjacent to the first and second single height cells SHC1 and SHC2 in a second direction D2.

A separation structure DB may be provided between the first single height cell SHC1 and the double height cell DHC, and between the second single height cell SHC2 and the double height cell DHC. An active region of the double height cell DHC may be electrically separated from an active region of each of the first and second single height cells SHC1 and SHC2 by the separation structure DB.

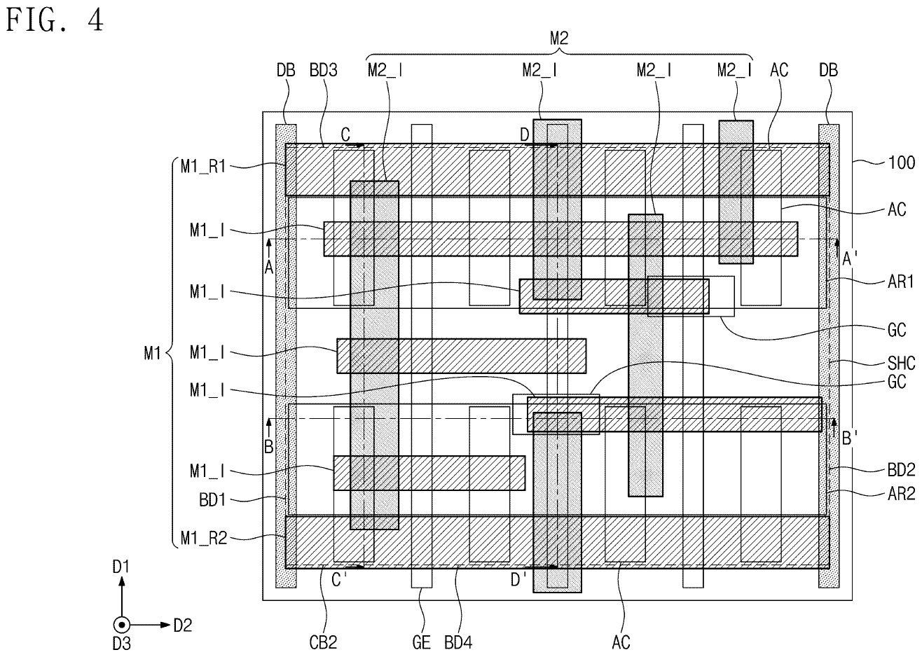

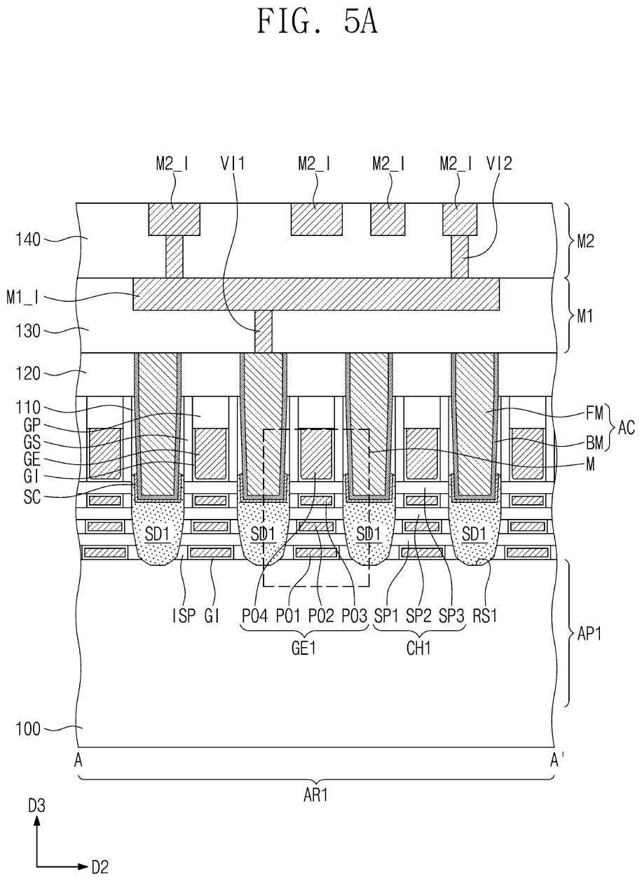

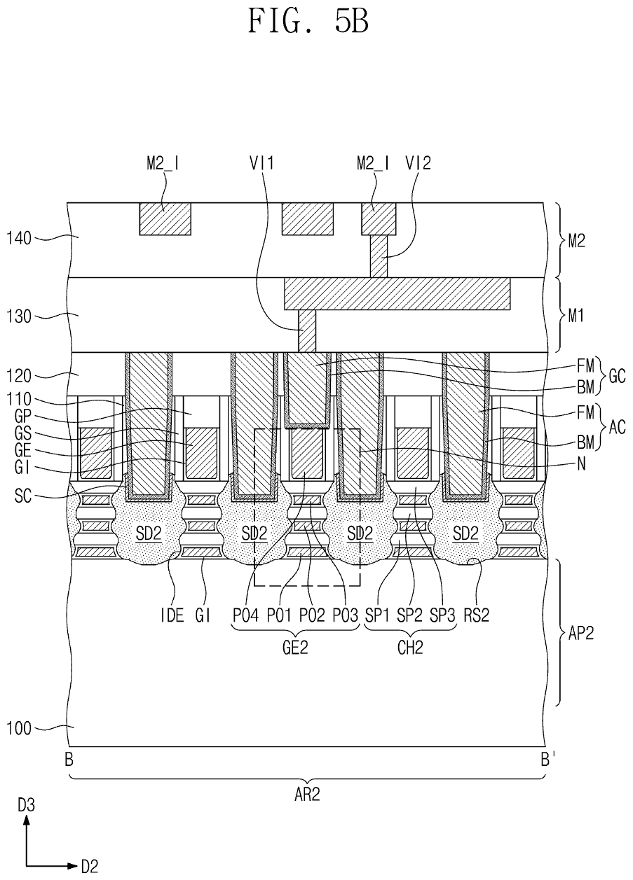

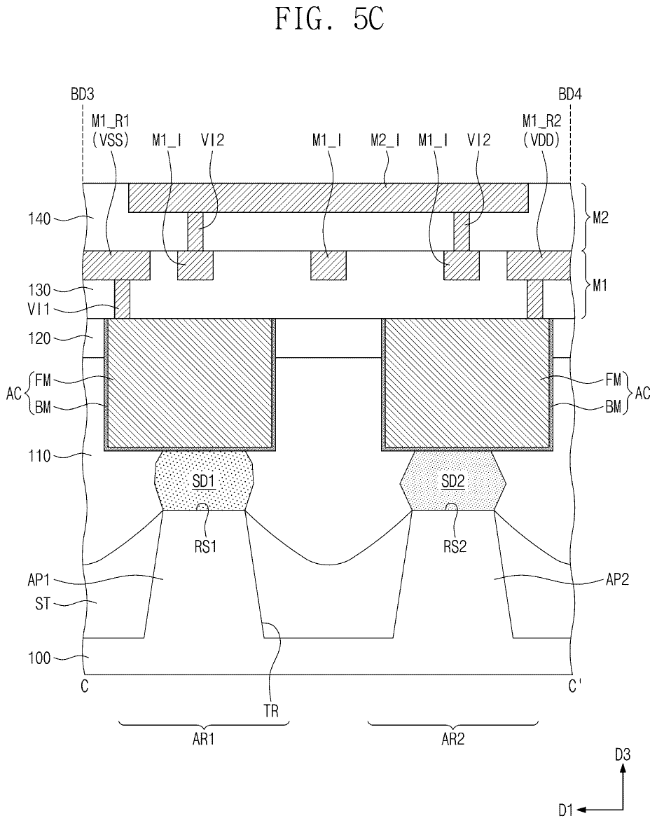

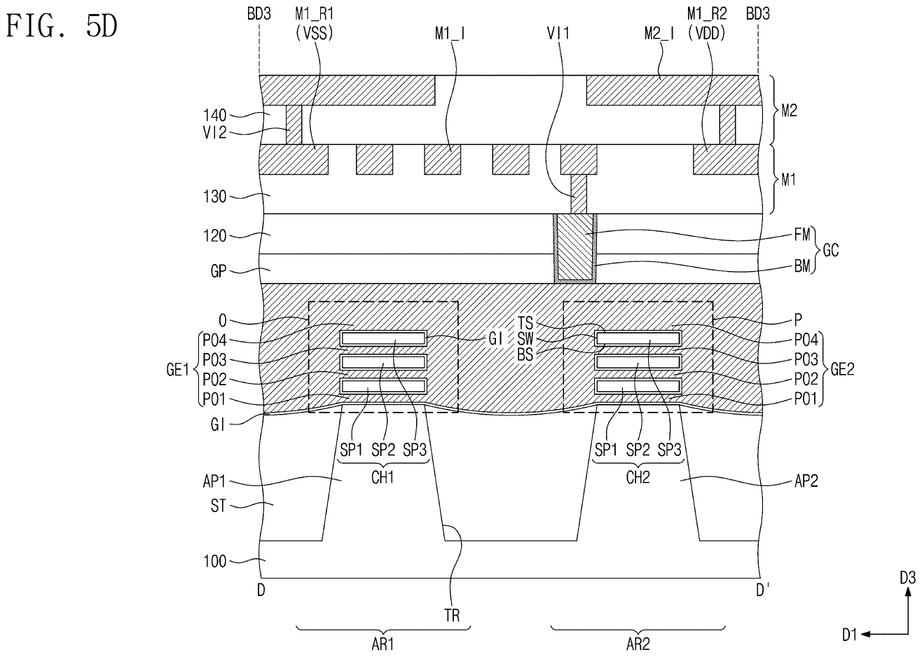

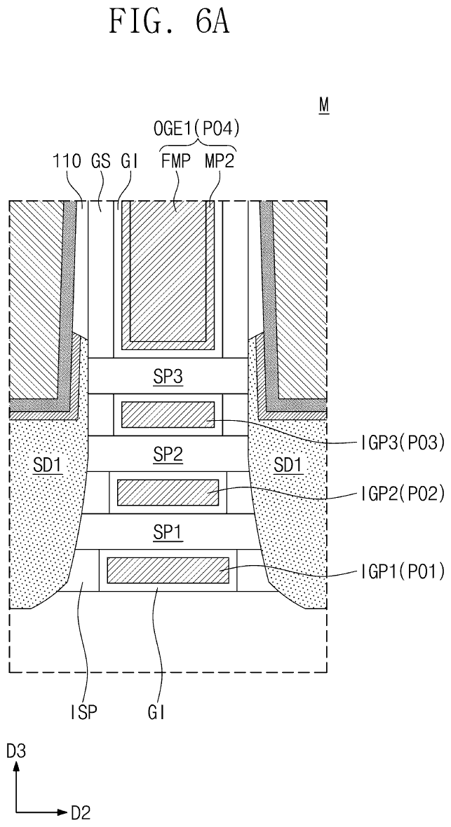

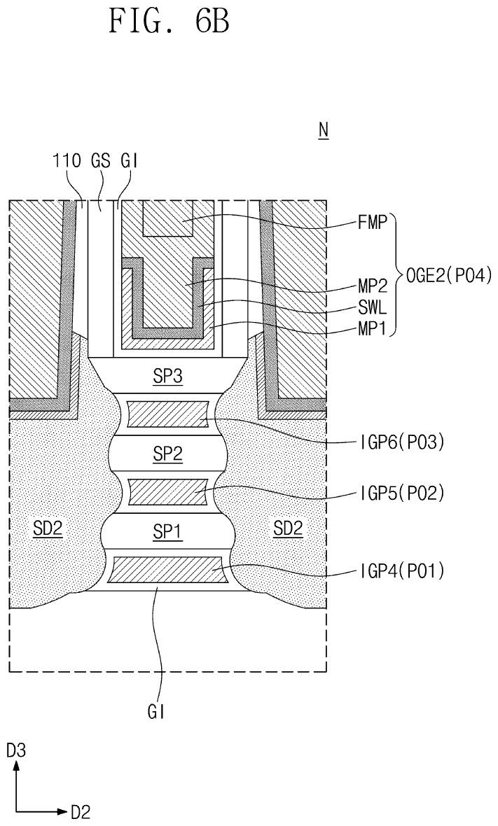

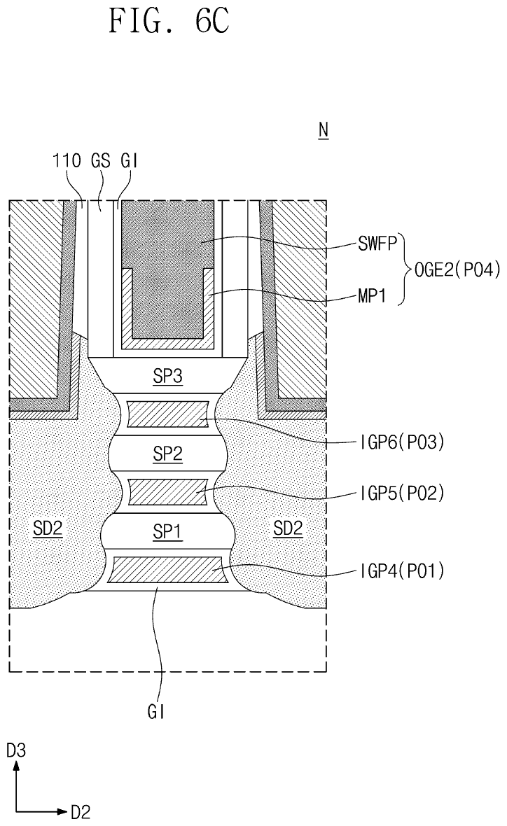

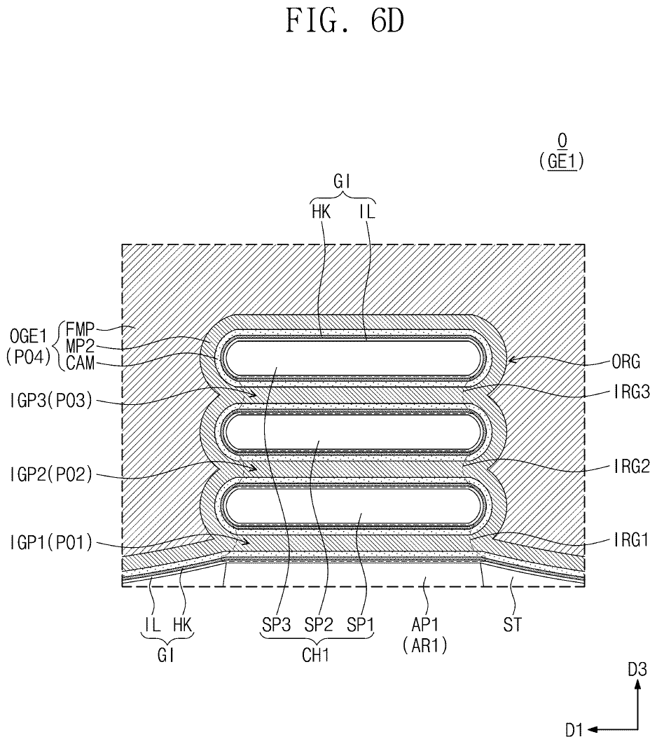

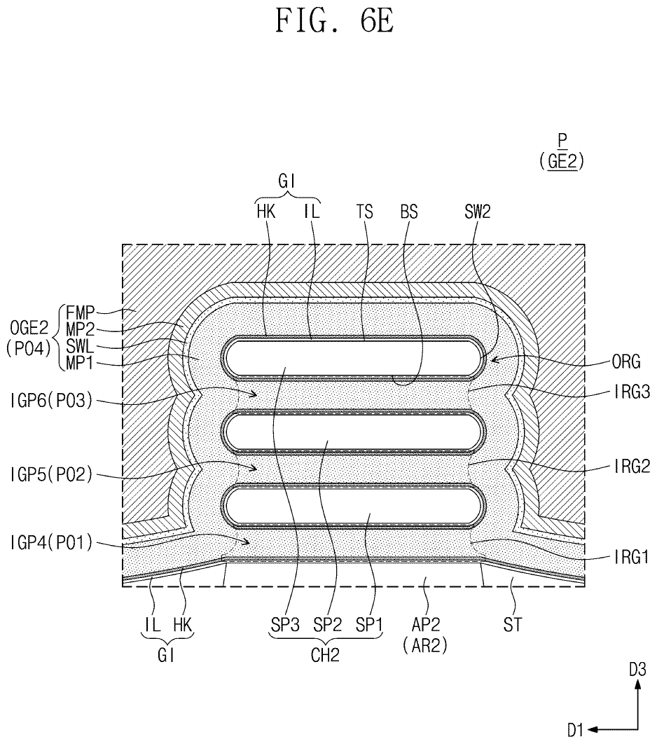

FIG. 4 is a plan view for describing the semiconductor device according to embodiments of the inventive concept. FIGS. 5A, 5B, 5C, and 5D are cross-sectional views taken along line A-A′, line B-B′, line C-C′ and line D-D′ of FIG. 4, respectively. FIG. 6A is an enlarged diagram of region M of FIG. 5A, and FIG. 6B is an enlarged diagram of region N of FIG. 5B. FIG. 6C is an enlarged diagram illustrating another embodiment of region N of FIG. 5B. FIG. 6D is an enlarged diagram of region O of FIG. 5D, and FIG. 6E is an enlarged diagram of region P of FIG. 5D. The semiconductor device illustrated in FIGS. 4 and 5A to 5D is an example more specifically illustrating the single height cell SHC of FIG. 1.

Referring to FIGS. 4 and 5A to 5D, the single height cell SHC may be provided on the substrate 100. Logic transistors that constitute a logic circuit may be disposed on the single height cell SHC. The substrate 100 may be a semiconductor substrate or a compound semiconductor substrate including silicon, germanium, silicon-germanium, or the like. For example, the substrate 100 may be a silicon substrate.

The substrate 100 may include the first active region AR1 and the second active region AR2. Each of the first and second active regions AR1 and AR2 may extend in the second direction D2. According to an embodiment, the first active region AR1 (including region M) may be an NMOSFET region, and the second active region AR2 (including region N) may be a PMOSFET region.

A first active pattern AP1 and a second active pattern AP2 may be defined by a trench TR formed therebetween on the substrate 100. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be parts vertically protruding as parts of the substrate 100. That is, the first and second active patterns AP1 and AP2 may be vertically protruding portions of the substrate 100.

An element separation layer ST may be provided on the substrate 100. The element separation layer ST may fill the trench TR. The element separation layer ST may include a silicon oxide layer. The element separation layer ST may not cover first and second channel patterns CH1 and CH2 to be described later.

A first channel pattern CH1 may be provided on the first active pattern AP1. A second channel pattern CH2 may be provided on the second active pattern AP2. Each of the first channel pattern CH1 and the second channel pattern CH2 may include respective semiconductor patterns, such as a first semiconductor pattern SP1, a second semiconductor pattern SP2, and a third semiconductor pattern SP3, sequentially stacked. The first to third semiconductor patterns SP1, SP2, and SP3 may be spaced apart from each other in a vertical direction (that is, a third direction D3).

Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon, more specifically, single-crystalline silicon. According to an embodiment of the inventive concept, the first to third semiconductor patterns SP1, SP2, and SP3 may be stacked nanosheets.

A plurality of first source/drain patterns SD1 may be provided on the first active pattern AP1. A plurality of first recesses RS1 may be formed on the first active pattern AP1. The first source/drain patterns SD1 may be respectively provided in first recesses RS1. The first source/drain patterns SD1 may be impurity regions having a first conductive type (for example, an N-type). The first channel pattern CH1 may be interposed between a pair of first source/drain patterns SD1. In other words, the stacked first to third semiconductor patterns SP1, SP2, and SP3 may connect the pair of first source/drain patterns SD1 to each other.

A plurality of second source/drain patterns SD2 may be provided on the second active pattern AP2. A plurality of second recesses RS2 may be formed on the second active pattern AP2. The second source/drain patterns SD2 may be respectively provided in second recesses RS2. The second source/drain patterns SD2 may be impurity regions having a second conductive type (for example, a P-type). The second channel pattern CH2 may be interposed between a pair of second source/drain patterns SD2. In other words, the stacked first to third semiconductor patterns SP1, SP2, and SP3 may connect the pair of second source/drain patterns SD2 to each other.

The first and second source/drain patterns SD1 and SD2 may be epitaxial patterns formed in a selective epitaxial growth (SEG) process. For example, a top surface of each of the first and second source/drain patterns SD1 and SD2 may be located at a higher level (e.g., a greater distance from the substrate 100 in direction D3) than a top surface of the third semiconductor pattern SP3. For another example, at least one top surface of the first and second source/drain patterns SD1 and SD2 may be located at the substantially same level as the top surface of the third semiconductor pattern SP3.

According to an embodiment of the inventive concept, the first source/drain patterns SD1 may include the same semiconductor element (for example, Si) as the substrate 100. The second source/drain patterns SD2 may include a semiconductor element (for example, SiGe) having a greater lattice parameter than a semiconductor element (for example, Si) of the substrate 100. Accordingly, a pair of second source/drain patterns SD2 may supply a compressive stress to the second channel pattern CH2 therebetween.

According to an embodiment of the inventive concept, a sidewall of the second source/drain pattern SD2 may have an uneven embossed form. In other words, the sidewall of the second source/drain pattern SD2 may have a wavy profile or cross-section. The sidewall of the second source/drain pattern SD2 may protrude toward first to third parts PO1, PO2, and PO3 of a gate electrode GE to be described later.

Gate electrodes GE1 and GE2 may be provided on the first and second channel patterns CH1 and CH2, respectively. Each of the gate electrodes GE1 and GE2 may cross the first and second channel patterns CH1 and CH2, and may extend in the first direction D1. Each of the gate electrodes GE1 and GE2 may vertically overlap the first and second channel patterns CH1 and CH2. Components or layers described with reference to “overlap” in a particular direction may be at least partially obstructed by one another when viewed along a line extending in the particular direction or in a plane perpendicular to the particular direction. The gate electrodes GE may be arranged having a first pitch in the second direction D2 (see FIG. 4).

Each of the first gate electrode GE1 and the second gate electrode GE2 may include respective parts, such as a first part PO1 interposed between the active pattern AP1 or AP2 and the first semiconductor pattern SP1, a second part PO2 interposed between the first semiconductor pattern SP1 and the second semiconductor pattern SP2, a third part PO3 interposed between the second semiconductor pattern SP2 and the third semiconductor pattern SP3, and a fourth part PO4 on the third semiconductor pattern SP3.

Referring to FIG. 5D, the gate electrodes GE1 and GE2 may be provided on a top surface, a bottom surface, and both (i.e., opposing) sidewalls of each of the first to third semiconductor patterns SP1, SP2, and SP3. In other words, a transistor according to the present embodiment may be a three-dimensional field effect transistor (for example, a MBCFET or a GAAFET) in which the gate electrodes GE1 and GE2 three-dimensionally surround channels thereof. The term “surround” (or “cover” or “fill”) as may be used herein may not require completely surrounding (or covering or filling) the described elements or layers, but may, for example, refer to partially surrounding (or covering or filling) the described elements or layers, for example, with voids, spaces, or other discontinuities throughout.

Inner spacers ISP may be respectively interposed between the first source/drain pattern SD1 and the first to third parts PO1, PO2, and PO3 of the first gate electrode GE1 on the first active region AR1. Each of the first to third parts PO1, PO2, and PO3 of the gate electrode GE may be spaced apart from the first source/drain pattern SD1 with the inner spacer ISP therebetween. The inner spacer ISP may reduce or prevent leakage current from the gate electrode GE.

Referring back to FIG. 4, and 5A to 5D, a pair of gate spacers GS may be respectively disposed on both (i.e., opposing) sidewalls of the fourth part PO4 of the gate electrode GE1 or GE2. The gate spacers GS may extend along the gate electrode GE1 or GE2 in the first direction D1. According to an embodiment, the gate spacers GS may include at least one of SiCN, SiCON, or SiN. According to another embodiment, the gate spacers GS may include a multi-layer composed of at least two of SiCN, SiCON, or SiN. According to an embodiment of the inventive concept, the gate spacer GS may include a Si-containing insulating material. The gate spacer GS may function as an etch stop layer during formation of active contact structures AC (see FIG. 4) to be described later. The active contact structures AC (see FIG. 4) may be formed self-aligned by the gate spacer GS.

A gate capping pattern GP may be provided on the gate electrodes GE1 and GE2. The gate capping pattern GP may extend along each of the gate electrodes GE1 and GE2 in the first direction D1. The gate capping pattern GP may include a material having etching selectivity with respect to first and second interlayered insulating layers 110 and 120 to be described later. Specifically, the gate capping pattern GP may include at least one of SiON, SiCN, SiCON, or SiN.

A gate insulating layer GI may be interposed between the first gate electrode GE1 and the first channel pattern CH1, and between the second gate electrode GE2 and the second channel pattern CH2. The gate insulating layer GI may cover a top surface TS, a bottom surface BS, and both (i.e., opposing) sidewalls SW of each of the first to third semiconductor patterns SP1, SP2, and SP3. The gate insulating layer GI may cover a top surface of the element separation layer ST under the gate electrode GE.

According to an embodiment of the inventive concept, the gate insulating layer GI may include a silicon oxide layer, a silicon oxynitride layer, and/or a high-dielectric layer. For example, the gate insulating layer GI may have a structure in which a silicon oxide layer and a high-dielectric layer (which may also be referred to as a high-k dielectric) are stacked. The high-dielectric layer may include a high-dielectric material having a higher dielectric constant than silicon oxide. For example, the high-dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

According to another embodiment, the semiconductor device according to the inventive concept may include a negative capacitance FET using a negative capacitor. For example, the gate insulating layer GI may include a ferroelectric material layer having ferroelectric characteristics, and a paraelectric material layer having paraelectric characteristics.

The ferroelectric material layer may have a negative capacitance, and the paraelectric material layer may have a positive capacitance. For example, when at least two capacitors are serially connected to each other, and each of the capacitors has a positive capacitance value, the total capacitance becomes smaller than capacitance of each individual capacitor. However, when at least one of two or more capacitors serially connected to each other has a negative capacitance value, the total capacitance may have a positive value and may be greater than an absolute value of capacitance of each individual capacitor.

When a ferroelectric material layer having a negative capacitance and a paraelectric material layer having a positive capacitance are serially connected to each other, the total capacitance of the ferroelectric material layer and the paraelectric material layer serially connected to each other may increase. A transistor including the ferroelectric material layer may have a subthreshold swing (SS) smaller than about 60 mV/decade at room temperature by using a phenomenon that the total capacitance increases.

The ferroelectric material layer may have ferroelectric characteristics. For example, the ferroelectric material layer may include at least one of hafnium oxide, hafnium zirconium oxide, barium strontium titanium oxide, barium titanium oxide, or lead zirconium titanium oxide. Here, the hafnium zirconium oxide may be, for example, hafnium oxide doped with zirconium (Zr). For another example, the hafnium zirconium oxide may be a compound of hafnium (Hf), zirconium (Zr) and oxygen (O).

The ferroelectric material layer may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be changed depending on which ferroelectric material the ferroelectric material layer includes.

When the ferroelectric material layer includes hafnium oxide, the dopant included in the ferroelectric material layer may include, for example, at least one of gadolinium (Gd), silicon (Si), zirconium (Zr), aluminum (Al), or yttrium (Y).

When the dopant is aluminum (Al), the ferroelectric material layer may include aluminum of about 3 at % to about 8 at %. Here, a ratio of the dopant may be a ratio of aluminum to a sum of hafnium and aluminum.

When the dopant is silicon (Si), the ferroelectric material layer may include silicon of about 2 at % to about 10 at %. When the dopant is yttrium (Y), the ferroelectric material layer may include yttrium (Y) of about 2 at % to about 10 at %. When the dopant is gadolinium (Gd), the ferroelectric material layer may include gadolinium (Gd) of about 1 at % to about 7 at %. When the dopant is zirconium (Zr), the ferroelectric material layer may include zirconium (Zr) of about 50 at % to about 80 at %.

The paraelectric material layer may have paraelectric characteristics. For example, the paraelectric material layer may include at least one of silicon oxide or metal oxide having a high-dielectric constant. For example, the metal oxide included in the paraelectric material layer may include at least one of hafnium oxide, zirconium oxide or aluminum oxide, but an embodiment of the inventive concept is not limited thereto.

The ferroelectric material layer and the paraelectric material layer may include the same material. The ferroelectric material layer may have ferroelectric characteristics, but the paraelectric material layer may not have the ferroelectric characteristics. For example, when the ferroelectric material layer and the paraelectric material layer include hafnium oxide, a crystal structure of hafnium oxide included in the ferroelectric material layer is different from a crystal structure of the hafnium oxide included in the paraelectric material layer.

The ferroelectric material layer may have a thickness suitable for showing or exhibiting ferroelectric characteristics. For example, the ferroelectric material layer may have a thickness of about 0.5 nm to about 10 nm, but an embodiment of the inventive concept is not limited thereto. Since each of the ferroelectric materials may have a critical thickness that begins to show or exhibit the ferroelectric characteristics, the ferroelectric material layer may have a different thickness depending on a ferroelectric material thereof.

For example, the gate insulating layer GI may include one ferroelectric material layer. For another example, the gate insulating layer GI may include a plurality of ferroelectric material layers spaced apart from each other. The gate insulating layer GI may have a stack layer structure in which a plurality of ferroelectric material layers and a plurality of paraelectric material layers are alternately stacked.

Referring back to FIGS. 4 and 5A to 5D, the gate electrode GE1 or GE2 may include a first metal pattern, and a second metal pattern on the first metal pattern. The first metal pattern may be provided on the gate insulating layer GI to be adjacent to the first to third semiconductor patterns SP1, SP2, and SP3. The first metal pattern may include a work function metal that controls a threshold voltage of a transistor. A targeted threshold voltage of the transistor may be achieved by controlling a thickness and a composition of the first metal pattern. For example, the first to third parts PO1, PO2, and PO3 of the gate electrode GE may be composed of the first metal pattern, which is made of the work function metal.

The first metal pattern may include a metal nitride layer. For example, the first metal pattern may include nitrogen (N) and at least one metal selected from the group consisting of titanium (Ti), tantalum (Ta), aluminum (Al), tungsten (W), and molybdenum (Mo). Moreover, the first metal pattern may further include carbon (C). The first metal pattern may include a plurality of stacked work function metal layers.

The second metal pattern may include metal having lower resistance than that of the first metal pattern. For example, the second metal pattern may include at least one metal selected from the group consisting of titanium (Ti), tantalum (Ta), aluminum (Al), and tungsten (W). For example, the fourth part PO4 of the gate electrode GE1 or GE2 may include the first metal pattern and the second metal pattern on the first metal pattern. The fourth part PO4 of gate electrode GE1 or GE2 according to the inventive concept will be more specifically described later with reference to FIGS. 6A to 6E.

The first interlayered insulating layer 110 may be provided on the substrate 100. The first interlayered insulating layer 110 may cover the gate spacers GS and the first and second source/drain patterns SD1 and SD2. A top surface of the first interlayered insulating layer 110 may be substantially coplanar with a top surface of the gate capping pattern GP and a top surface of the gate spacer GS.

The second interlayered insulating layer 120 may be disposed on the first interlayered insulating layer 110. A third interlayered insulating layer 130 may be provided on the second interlayered insulating layer 120. A fourth interlayered insulating layer 140 may be provided on the third interlayered insulating layer 130. For example, the first to fourth interlayered insulating layers 110, 120, 130, and 140 may each include a silicon oxide layer.

The single height cell SHC may have a first boundary BD1 and a second boundary BD2 opposed to each other in the second direction D2. The first and second boundaries BD1 and BD2 may extend in the first direction D1. The single height cell SHC may have a third boundary BD3 and a fourth boundary BD4 opposed to each other in the first direction D1. The third and fourth boundaries BD3 and BD4 may extend in the second direction D2.

A pair of separation structures DB opposed to each other in the second direction D2 may be provided on both (i.e., opposing) sides of the single height cell SHC. For example, the pair of separation structures DB may be respectively provided on the first and second boundaries BD1 and BD2 of the single height cell SHC. The separation structure DB may extend parallel to the gate electrodes GE in the first direction D1. A pitch between the separation structure DB and the gate electrode GE adjacent thereto may be the same as the first pitch.

The separation structure DB may penetrate the first interlayered insulating layer 110 and the second interlayered insulating layer 120 to extend to the insides of the first and second active patterns AP1 and AP2. The separation structure DB may penetrate an upper portion of each of the first and second active patterns AP1 and AP2. The separation structure DB may electrically separate an active region of single height cell SHC from an active region of another cell adjacent thereto.

Active contacts AC penetrating the first and second interlayered insulating layers 110 and 120 to be respectively electrically connected to the first and second source/drain patterns SD1 and SD2 may be provided. A pair of active contacts AC may be respectively provided on both (i.e., opposing) sides of the gate electrode GE. On or in a plan view, the active contacts AC may have a form of a bar extending in the first direction D1.

The active contacts AC may be self-aligned contacts. In other words, the active contacts AC may be formed self-aligned using the gate capping pattern GP and the gate spacer GS. For example, the active contacts AC may be disposed so as to be adjacent to sidewalls of the gate spacer GS. Although not shown, the active contacts AC may partially cover a top surface of the gate capping pattern GP.

A metal-semiconductor compound layer SC, for example, a silicide layer may be interposed between the active contact AC and the first source/drain pattern SD1, and between the active contact AC and the second source/drain pattern SD2. The active contacts AC may be respectively electrically connected to the source/drain patterns SD1 and SD2 through the metal-semiconductor compound layer SC. For example, the metal-semiconductor compound layer SC may include at least one of titanium-silicide, tantalum-silicide, tungsten-silicide, nickel-silicide, or cobalt-silicide.

Gate contacts GC penetrating the second interlayered insulating layer 120 and the gate capping pattern GP to be respectively electrically connected to the gate electrodes GE may be provided. On or in a plan view, the gate contacts GC may be disposed so as to respectively overlap the first active region AR1 and the second active region AR2. For example, the gate contact GC may be provided on the second active pattern AP2.

Although not shown, according to another embodiment of the inventive concept, an upper portion of the active contact AC adjacent to the gate contact GC may be filled with an upper insulating pattern. A bottom surface of the upper insulating pattern may be lower than a bottom surface of the gate contact GC, relative to the substrate 100. In other words, a top surface of the active contact AC adjacent to the gate contact GC may be lower than a bottom surface of the gate contact GC due to the upper insulating pattern. Accordingly, a short-circuit occurring when the gate contact GC is in contact with the active contact AC adjacent thereto may be prevented.

A first metal layer M1 may be provided in the third interlayered insulating layer 130. For example, the first metal layer M1 may include the first power wire M1_R1, the second power wire M1_R2 and first wires M1_I. The wires M1_R1, M1_R2 and M1_I of the first metal layer M1 may extend parallel to each other in the second direction D2.

Specifically, the first and second power wires M1_R1 and M1_R2 may be respectively provided on the third and fourth boundaries BD3 and BD4 of the single height cell SHC. The first power wire M1_R1 may extend along the third boundary BD3 in the second direction D2. The second power wire M1_R2 may extend along the fourth boundary BD4 in the second direction D2.

The first wires M1_I of the first metal layer M1 may be disposed between the first and second power wires M1_R1 and M1_R2. The first wires M1_I of the first metal layer M1 may be arranged with a second pitch in the first direction D1. The second pitch may be smaller than the first pitch. A line width of each of the first wires M1_I may be smaller than a line width of each of the first and second power wires M1_R1 and M1_R2.

The first metal layer M1 may further include first vias VI1. The first vias VI1 may be respectively provided under the wires M1_R1, M1_R2 and M1_I of the first metal layer M1. The active contact AC and the wire of the first metal layer M1 may be electrically connected to each other through the first via VI1. The gate contact GC and the wire of the first metal layer M1 may be electrically connected to each other through the first via VI1.

The wire of the first metal layer M1 and the first via VI1 thereunder may be respectively formed in separate processes. In other words, each of the wire of the first metal layer M1 and the first via VI1 may be formed in a single damascene process. The semiconductor device according to the present embodiment may be formed using a process of manufacturing a semiconductor device having a design rule less than about 20 nm.

A second metal layer M2 may be provided in the fourth interlayered insulating layer 140. The second metal layer M2 may include a plurality of second wires M2_I. Each of the second wires M2_I of the second metal layer M2 may have a form of a line or a bar extending in the first direction D1. In other words, the second wires M2_I may extend parallel to each other in the first direction D1.

The second metal layer M2 may further include second vias VI2 respectively provided under the second wires M2_I. The wire of the first metal layer M1 and the wire of the second metal layer M2 may be electrically connected to each other through the second via VI2. For example, the wire of the second metal layer M2 and the second via VI2 thereunder may be formed together in a dual damascene process.

The wire of the first metal layer M1 and the wire of the second metal layer M2 may include the same conductive material or different conductive materials. For example, the wire of the first metal layer M1 and the wire of the second metal layer M2 may include at least one metal material selected from aluminum, copper, tungsten, molybdenum, ruthenium or cobalt. Although not shown, metal layers (for example, M3, M4, M5 and the like) stacked on the fourth interlayered insulating layer 140 may be additionally disposed. Each of the stacked metal layers may include wires for routing between cells.

The first to fourth parts PO1 to PO4 of the first gate electrode GE1 and the first to fourth parts PO1 to PO4 of the second gate electrode GE2 will be described with reference to FIGS. 6A, 6B, 6D and 6E in more detail.

Referring to FIG. 6A, the first gate electrode GE1 may include a first inner electrode IGP1 between the first active pattern AP1 and the first semiconductor pattern SP1, a second inner electrode IGP2 between the first semiconductor pattern SP1 and the second semiconductor pattern SP2, and a third inner electrode IGP3 between the second semiconductor pattern SP2 and the third semiconductor pattern SP3. The third inner electrode IGP3 may be an uppermost inner electrode among the first to third inner electrodes IGP1 to IGP3. The first to third inner electrodes IGP1 to IGP3 may respectively correspond to the first to third parts PO1, PO2, and PO3 described above. The first gate electrode GE1 may further include a first outer electrode OGE1 on the first to third inner electrodes IGP1 to IGP3. The first outer electrode OGE1 may correspond to the fourth part PO4 described above.

Referring to FIG. 6B, the second gate electrode GE2 may include a fourth inner electrode IGP4 between the first active pattern AP1 and the first semiconductor pattern SP1, a fifth inner electrode IGP5 between the first semiconductor pattern SP1 and the second semiconductor pattern SP2, and a sixth inner electrode IGP6 between the second semiconductor pattern SP2 and the third semiconductor pattern SP3. The sixth inner electrode IGP6 may be an uppermost inner electrode among the fourth to sixth inner electrodes IGP4 to IGP6. The fourth to sixth inner electrodes IGP4 to IGP6 may respectively correspond to the first to third parts PO1, PO2, and PO3 described above. The second gate electrode GE2 may further include a second outer electrode OGE2 on the fourth to sixth inner electrodes IGP4 to IGP6. The second outer electrode OGE2 may correspond to the fourth part PO4 described above.

The first gate electrode GE1 and the second gate electrode GE2 may be connected to each other to constitute one gate electrode GE extending in the first direction D1. The first gate electrode GE1 and the second gate electrode GE2 may share the first and second outer electrodes OGE1 and OGE2.

Referring to FIGS. 6A and 6D, the first gate electrode GE1 on the first active region AR1 will be described in more detail. The gate insulating layer GI may cover a surface of each of the first to third semiconductor patterns SP1, SP2, and SP3. The gate insulating layer GI may include an interface layer IL and a high-dielectric layer HK on the interface layer IL. The interface layer IL may directly cover the surface of each of the first to third semiconductor patterns SP1, SP2, and SP3. The high-dielectric layer HK may be spaced apart from the first to third semiconductor patterns SP1, SP2, and SP3 with the interface layer IL therebetween. The high-dielectric layer HK may have a greater thickness than the interface layer IL.

The first gate electrode GE1 may include the first to third inner electrodes IGP1 to IGP3 and the first outer electrode OGE1. A first inner region IRG1 may be defined between the first active pattern AP1 and the first semiconductor pattern SP1, a second inner region IRG2 may be defined between the first semiconductor pattern SP1 and the second semiconductor pattern SP2, and a third inner region IRG3 may be defined between the second semiconductor pattern SP2 and the third semiconductor pattern SP3. The first to third inner electrodes IGP1 to IGP3 may be respectively provided to or may extend in the first to third inner regions IRG1, IRG2, and IRG3. The first to third inner electrodes IGP1 to IGP3 may be provided on the gate insulating layer GI.

The first to third inner electrodes IGP1 to IGP3 may include the same material. The first to third inner electrodes IGP1 to IGP3 may include a first work function metal that controls a threshold voltage of a transistor. A targeted threshold voltage of the transistor may be achieved by controlling a composition in the first work function metal. For example, the first work function metal may be an N-type work function metal having a relatively low work function.

According to an embodiment, the first to third inner electrodes IGP1 to IGP3 may include a metal nitride layer. The first to third inner electrodes IGP1 to IGP3 may include nitrogen (N) and at least one metal selected from the group consisting of titanium (Ti), tantalum (Ta), niobium (Nb), aluminum (Al), and molybdenum (Mo). For example, the first to third inner electrodes IGP1 to IGP3 may include titanium nitride (TiN), tantalum nitride (TaN), titanium oxynitride (TiON), titanium silicon nitride (TiSiN), titanium aluminum nitride (TiAlN) or molybdenum nitride (MoN).

According to another embodiment, the first to third inner electrodes IGP1 to IGP3 may include metal oxynitride, metal oxycarbide, or metal oxynitride carbide. Here, the metal may be selected from the group consisting of Ti, Ta, Nb, Al and Mo described above.

The first to third inner electrodes IGP1 to IGP3 of the first gate electrode GE1 and the first to third semiconductor patterns SP1, SP2, and SP3 of the first channel pattern CH1 may constitute a fin structure. In other words, the fin structure may include the first to third inner electrodes IGP1 to IGP3 and the first to third semiconductor patterns SP1, SP2, and SP3 alternately stacked. The fin structure may have a form of a fin protruding from the first active pattern AP1 in a vertical direction (that is, the third direction D3). The fin structure may protrude higher than a top surface of the element separation layer ST.

A remaining region surrounding the fin structure may be defined as an outer region ORG. The first outer electrode OGE1 may be provided in the outer region ORG. The first outer electrode OGE1 on the first active region AR1 may surround the fin structure. For example, the first outer electrode OGE1 may be provided on both (i.e., opposing) sidewalls and a top surface of the fin structure. In other words, the first outer electrode OGE1 may not be provided in spaces between the first to third semiconductor patterns SP1, SP2, and SP3 adjacent to each other.

The first outer electrode OGE1 may include a second metal pattern MP2 and a filling metal pattern FMP sequentially stacked. The first outer electrode OGE1 may not include tungsten (W). The second metal pattern MP2 and the filling metal pattern FMP will be described later.

Referring to FIGS. 6B and 6E, the second gate electrode GE2 on the second active region AR2 will be described in more detail. The gate insulating layer GI may cover a surface of each of the first to third semiconductor patterns SP1, SP2, and SP3. The gate insulating layer GI may include the interface layer IL and the high-dielectric layer HK on the interface layer IL. The interface layer IL may directly cover the surface of each of the first to third semiconductor patterns SP1, SP2, and SP3. The high-dielectric layer HK may be spaced apart from the first to third semiconductor patterns SP1, SP2, and SP3 with the interface layer IL therebetween. The high-dielectric layer HK may have a greater thickness than the interface layer IL.

The second gate electrode GE2 may include the fourth to sixth inner electrodes IGP4 to IGP6 and the second outer electrode OGE2. The first inner region IRG1 may be defined between the second active pattern AP2 and the first semiconductor pattern SP1, the second inner region IRG2 may be defined between the first semiconductor pattern SP1 and the second semiconductor pattern SP2, and the third inner region IRG3 may be defined between the second semiconductor pattern SP2 and the third semiconductor pattern SP3. The fourth to sixth inner electrodes IGP4 to IGP6 may be respectively provided to or may extend in the first to third inner regions IRG1, IRG2, and IRG3. The fourth to sixth inner electrodes IGP4 to IGP6 may be provided on the gate insulating layer GI.

The fourth to sixth inner electrodes IGP4 to IGP6 may include the same material as each other. The fourth to sixth inner electrodes IGP4 to IGP6 may include a second work function metal that controls a threshold voltage of a transistor. A targeted threshold voltage of the transistor may be achieved by controlling a composition in the second work function metal. For example, the second work function metal may be a P-type work function metal having a relatively high work function.

According to an embodiment, the fourth to sixth inner electrodes IGP4 to IGP6 may include a metal nitride layer. The fourth to sixth inner electrodes IGP4 to IGP6 may include nitrogen (N) and at least one metal selected from the group consisting of titanium (Ti), tantalum (Ta), niobium (Nb), aluminum (Al), tungsten (W) and molybdenum (Mo). For example, the fourth to sixth inner electrodes IGP4 to IGP6 may include titanium nitride (TiN), tantalum nitride (TaN), titanium oxynitride (TiON), titanium silicon nitride (TiSiN), titanium aluminum nitride (TiAlN) tungsten carbon nitride (WCN) or molybdenum nitride (MoN).

According to another embodiment, the fourth to sixth inner electrodes IGP4 to IGP6 may include metal oxynitride, metal oxycarbide, or metal oxynitride carbide. Here, the metal may be selected from the group consisting of Ti, Ta, Nb, Al, W and Mo described above.

The fourth to sixth inner electrodes IGP4 to IGP6 of the second gate electrode GE2 and the first to third semiconductor patterns SP1, SP2, and SP3 of the second channel pattern CH2 may constitute a fin structure. In other words, the fin structure may include the fourth to sixth inner electrodes IGP4 to IGP6 and the first to third semiconductor patterns SP1, SP2, and SP3 alternately stacked. The fin structure may have a form of a fin protruding from the second active pattern AP2 in a vertical direction (that is, the third direction D3). The fin structure may protrude higher than a top surface of the element separation layer ST.

A remaining region surrounding the fin structure may be defined as the outer region ORG. The second outer electrode OGE2 may be provided in the outer region ORG. The second outer electrode OGE2 on the second active region AR2 may surround the fin structure. For example, the second outer electrode OGE2 may be provided on both (i.e., opposing) sidewalls and a top surface of the fin structure. In other words, the second outer electrode OGE2 may not be provided in spaces between the first to third semiconductor patterns SP1, SP2, and SP3 adjacent to each other.

The second outer electrode OGE2 may include a first metal pattern MP1, a metal liner pattern SWL, the second metal pattern MP2 and the filling metal pattern FMP sequentially stacked. The first metal pattern MP1 may conformally cover a surface of the fin structure. The first metal pattern MP1 may directly cover sidewalls of the exposed fourth to sixth inner electrodes IGP4 to IGP6 and the exposed high-dielectric layer HK of the fin structure. The term “exposed” may be used to describe relationships between elements and/or certain intermediate processes in fabricating a completed semiconductor device, but may not necessarily require exposure of the particular region, layer, structure or other element in the context of the completed device.

The metal liner pattern SWL may cover the first metal pattern MP1. The second metal pattern MP2 may be provided on the metal liner pattern SWL to be spaced apart or separated from the first metal pattern MP1 by the metal liner pattern SWL.

The first metal pattern MP1 may include the first work function metal that controls a threshold voltage of a transistor. A targeted threshold voltage of the transistor may be achieved by controlling a composition in or of the first work function metal. For example, the first work function metal may be a P-type work function metal having a relatively high work function. The first metal pattern MP1 may include metal nitride, metal oxynitride, metal oxycarbide, or metal oxynitride carbide. Here, the metal may be selected from the group consisting of Ti, Ta, Nb, Al, W and Mo.

The first metal pattern MP1 may have a smaller work function than the fourth to sixth inner electrodes IGP4 to IGP6. In order that the first metal pattern MP1 has a smaller work function than the fourth to sixth inner electrodes IGP4 to IGP6, a material composition of the first metal pattern MP1 may be differently controlled from material compositions of the fourth to sixth inner electrodes IGP4 to IGP6.

For example, the first metal pattern MP1 may include titanium silicon nitride (TiSiN) or titanium aluminum nitride (TiAlN), and a first inner gate electrode IGEa may include titanium nitride (TiN). For another example, each of the first metal pattern MP1 and the first inner gate electrode IGEa may include titanium silicon nitride (TiSiN) or titanium aluminum nitride (TiAlN).

Representatively, the first metal pattern MP1 may be provided on a top surface TS and both (i.e., opposing) sidewalls SW1 and SW2 of the third semiconductor pattern SP3. As described above, the sixth inner electrode IGP6 may be provided on the bottom surface BS of the third semiconductor pattern SP3. The first metal pattern MP1 may cover both (i.e., opposing) sidewalls of the sixth inner electrode IGP6. The first metal pattern MP1 may be in direct contact with the both (i.e., opposing) sidewalls of the sixth inner electrode IGP6.

The metal liner pattern SWL may be a liner layer interposed between the first metal pattern MP1 and the second metal pattern MP2. The metal liner pattern SWL may include a metal nitride layer. A capping pattern CAM or the metal liner pattern SWL may include nitrogen (N) and at least one metal selected from the group consisting of titanium (Ti), tantalum (Ta), aluminum (Al), tungsten (W) and molybdenum (Mo). For example, the metal liner pattern SWL may include tungsten (W). The metal liner pattern SWL may have a substantially uniform thickness.

The second metal pattern MP2 may be provided on the metal liner pattern SWL. The second metal pattern MP2 may include a second work function metal that controls a threshold voltage of a transistor. A targeted threshold voltage of the transistor may be achieved by controlling a composition in the second work function metal. For example, the second work function metal may be an N-type work function metal having a relatively low work function. The first metal pattern MP1 may have a work function different from that of the second metal pattern MP2.

The second metal pattern MP2 may include metal carbide. The second metal pattern MP2 may include titanium aluminum carbide (TiAlC), tantalum aluminum carbide (TaAlC), vanadium aluminum carbide (VAlC), titanium silicon carbide (TiSiC), or tantalum silicon carbide (TaSiC). The second metal pattern MP2 and the first metal pattern MP1 may be provided on a top surface and both (i.e., opposing) sidewalls of the fin structure.

The filling metal pattern FMP may be provided on the second metal pattern MP2. The filling metal pattern FMP may have a lower resistance than the first and second metal patterns MP1 and MP2. For example, the filling metal pattern FMP may include at least one low-resistive metal of aluminum (Al), tungsten (W), titanium (Ti) or tantalum (Ta).

Referring back to FIG. 6B, the first metal pattern MP1 may have a U shape on or in a cross-sectional view. On or in a cross-sectional view, the metal liner pattern SWL may extend from a top surface of the first metal pattern MP1 onto an inner side surface of the first metal pattern MP1. The first metal pattern MP1 may have a substantially uniform first thickness, and the metal liner pattern SWL may have a substantially uniform second thickness. The first thickness may be the same as the second thickness. For another example, the first thickness may be greater than the second thickness.

The fourth inner electrode IGP4 may have a third thickness, and the fifth inner electrode IGP5 may have a fourth thickness, and the sixth inner electrode IGP6 may have a fifth thickness. The third to fifth thicknesses may be greater than the first thickness and the second thickness.

A PMOSFET of the second active region AR2 illustrated in FIG. 6E may have a relatively greater threshold voltage than a typical PMOSFET. The first to third inner electrodes IGP1 to IGP3 and the fourth to sixth inner electrodes IGP4 to IGP6 may have different material compositions. Accordingly, the first to third inner electrodes IGP1 to IGP3 on the first active region AR1 may have smaller work functions than the fourth to sixth inner electrodes IGP4 to IGP6 on the second active region AR2.

FIG. 6C is an enlarged diagram illustrating another embodiment of region N of FIG. 5B. Duplicate description for that made in FIG. 6B will be omitted, and differences therebetween will be mainly described.

Referring to FIG. 6C, the second outer electrode OGE2 may include the first metal pattern MP1 and a metal filling layer SWFP on the first metal pattern MP1. The metal filling layer SWFP may fill spaces between inner sidewalls of the gate insulating layer GI and inner sidewalls of the first metal pattern MP1. The metal filling layer SWFP may be substantially coplanar with the gate insulating layer GI adjacent to the second outer electrode OGE2.

The metal filling layer SWFP may include at least one low-resistive metal of aluminum (Al), tungsten (W), titanium (Ti) or tantalum (Ta). For example, the metal filling layer SWFP may include tungsten (W). For another example, the metal filling layer SWFP may include at least one selected from the group consisting of Ti, Ta, Nb, Al, W and Mo.

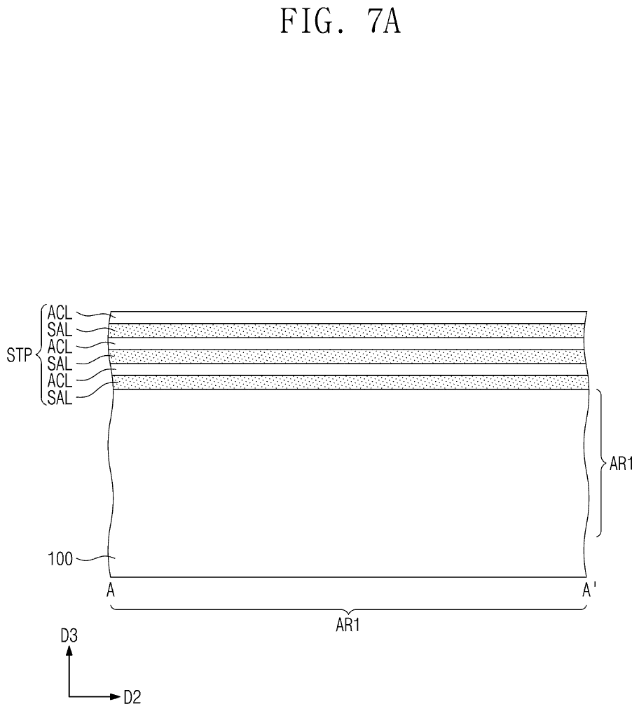

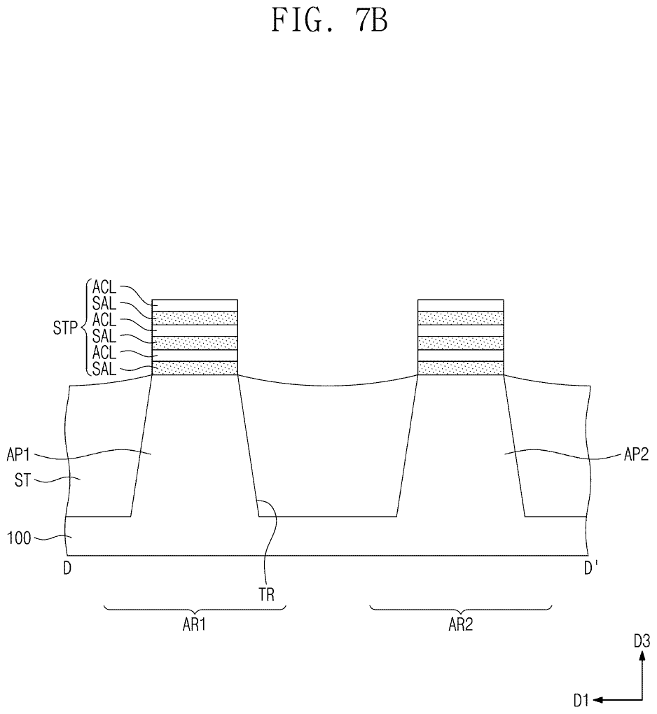

FIGS. 7A to 12D are cross-sectional views for describing a method for manufacturing a semiconductor device according to embodiments of the inventive concept.

Referring to FIGS. 7A and 7B, the substrate 100 including the first and second active regions AR1 and AR2 may be provided. Active layers ACL and sacrificial layers SAL alternately stacked may be formed on the substrate 100. The active layers ACL may include one of silicon (Si), germanium (Ge), and silicon-germanium (SiGe), and the sacrificial layers SAL may include another one of silicon (Si), germanium (Ge) and silicon-germanium (SiGe).

The sacrificial layers SAL may include a material having etching selectivity for the active layers ACL. For example, the active layers ACL may include silicon (Si), and the sacrificial layers SAL may include silicon-germanium (SiGe). Each of the sacrificial layers SAL may have a germanium (Ge) concentration of about 10 at % to about 30 at %.

Mask patterns may be respectively formed on the first and second active regions AR1 and AR2 of the substrate 100. The mask pattern may have a form of a line or a bar extending in the second direction D2.

A trench TR defining the first active pattern AP1 and the second active pattern AP2 may be formed by performing a patterning process using the mask patterns as etching masks. The first active pattern AP1 may be formed on the first active region AR1. The second active pattern AP2 may be formed on the second active region AR2.

A stack pattern STP may be formed on each of the first and second active patterns AP1 and AP2. The stack pattern STP may include the active layers ACL and the sacrificial layers SAL alternately stacked. The stack pattern STP may be formed together with the first and second active patterns AP1 and AP2 during the patterning process.

The element separation layer ST that fills the trench TR may be formed. Specifically, an insulating layer covering the first and second active patterns AP1 and AP2 and the stack patterns STP may be formed on a front surface of the substrate 100. The element separation layer ST may be formed by recessing the insulating layer until the stack patterns STP are exposed.

The element separation layer ST may include an insulating material such as a silicon oxide layer. The stack pattern STP may be exposed over the element separation layer ST. In other words, the stack patterns STP may vertically protrude over the element separation layer ST.

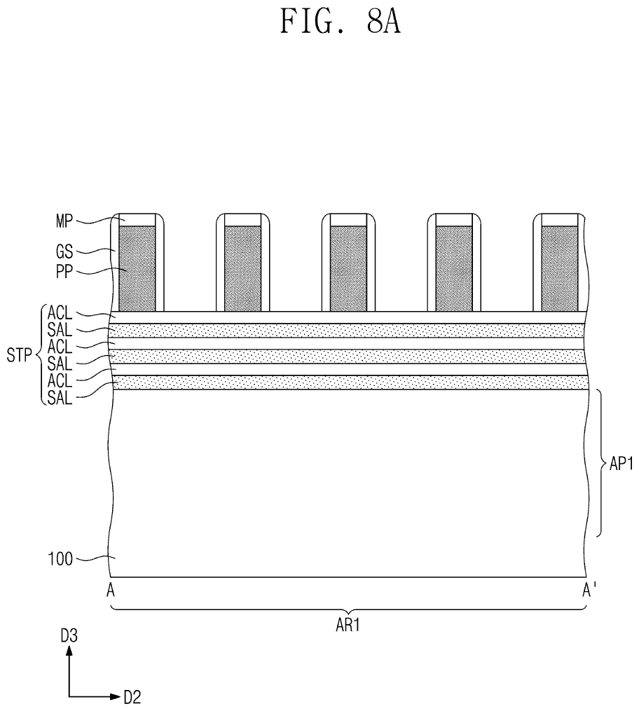

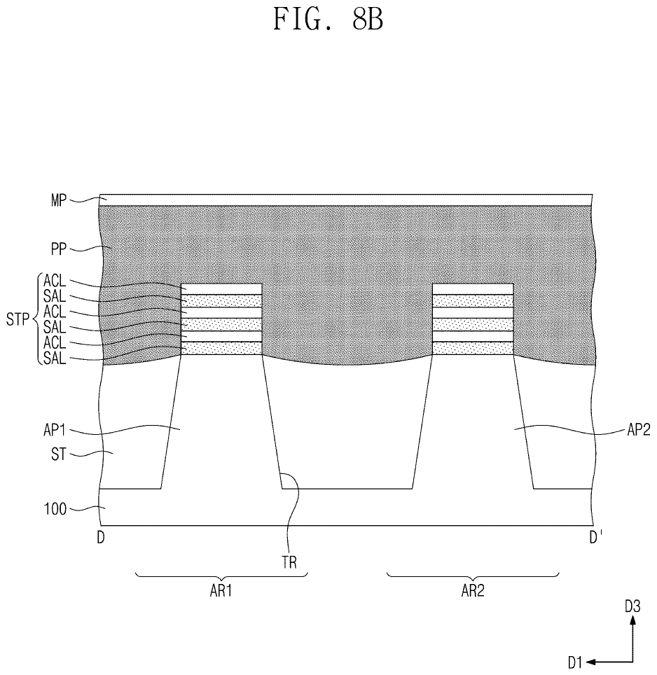

Referring to FIGS. 8A and 8B, sacrificial patterns PP crossing the stack patterns STP may be formed on the substrate 100. Each of the sacrificial patterns PP may be formed in a form of a line or a bar extending in the first direction D1. The sacrificial patterns PP may be arranged along the second direction D2 with the first pitch.

Specifically, forming the sacrificial patterns PP may include forming a sacrificial layer on the front surface of the substrate 100, forming hard-mask patterns MP on the sacrificial layer, and patterning the sacrificial layer using the hard-mask patterns MP as etching masks. The sacrificial layer may include polysilicon.

A pair of gate spacers GS may be formed on both (i.e., opposing) sidewalls of each of the sacrificial patterns PP. Forming the gate spacers GS may include conformally forming a gate spacer layer on the front surface of the substrate 100, and anisotropically etching the gate spacer layer. According to an embodiment of the inventive concept, the gate spacer GS may be a multi-layer including at least two layers.

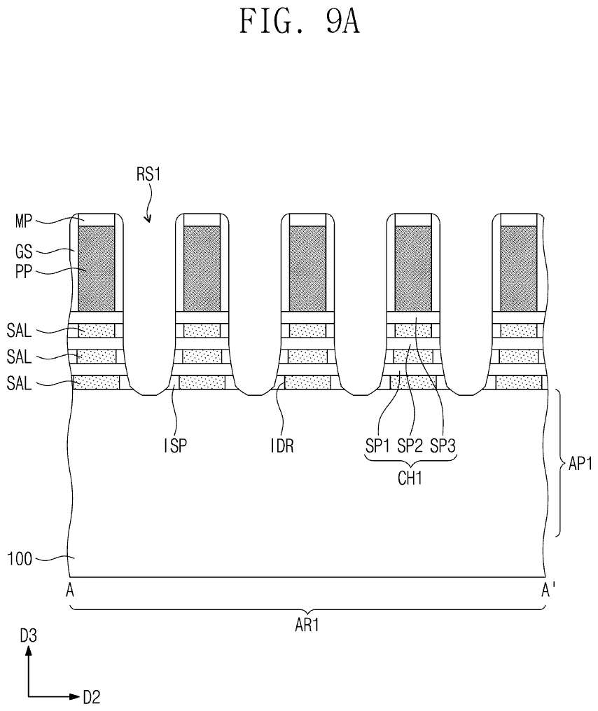

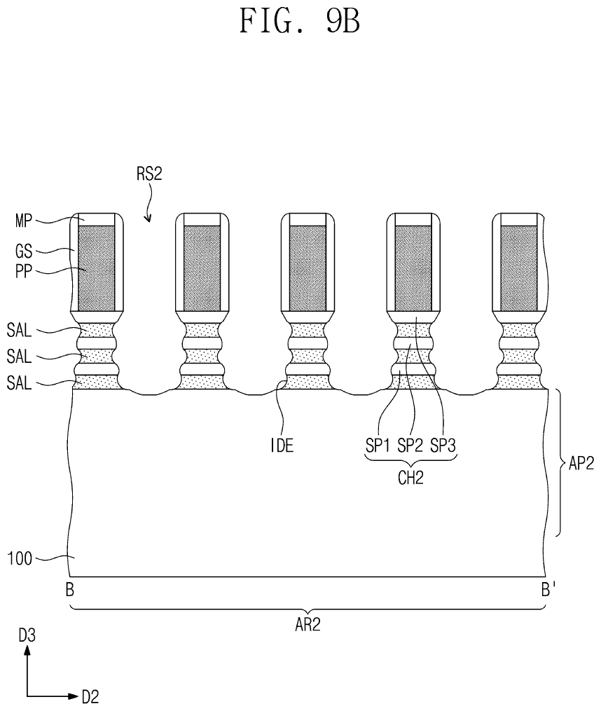

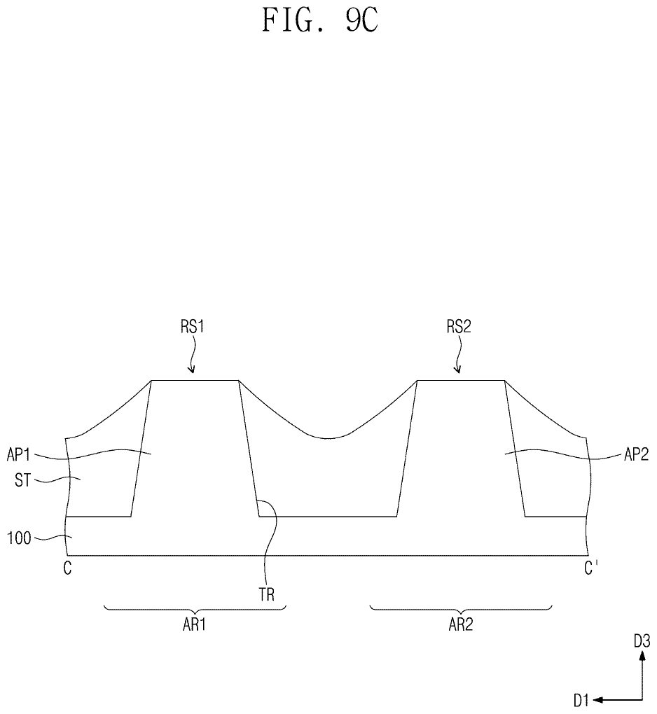

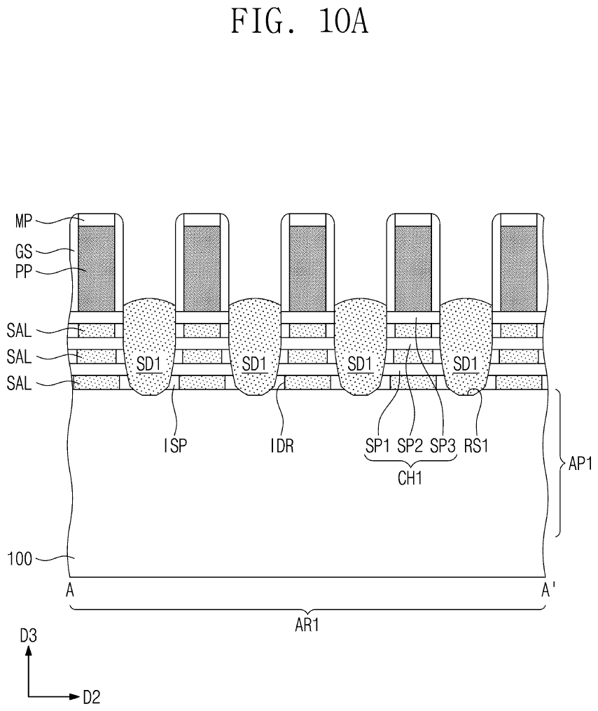

Referring to FIGS. 9A to 9C, the first recesses RS1 may be formed in the stack pattern STP on the first active pattern AP1. The second recesses RS2 may be formed in the stack pattern STP on the second active pattern AP2. During forming the first and second recesses RS1 and RS2, the element separation layer ST on both sides of each of the first and second active patterns AP1 and AP2 may be further recessed (see FIG. 9C).

Specifically, the first recesses RS1 may be formed by etching the stack pattern STP on the first active pattern AP1 by using the hard-mask patterns MP and the gate spacers GS as etching masks. The first recess RS1 may be formed between a pair of sacrificial patterns PP.

The first to third semiconductor patterns SP1, SP2, and SP3 sequentially stacked between the first recesses RS1 adjacent to each other may be respectively formed from the active layers ACL. The first to third semiconductor patterns SP1, SP2, and SP3 between the first recesses RS1 adjacent to each other may constitute the first channel pattern CH1.

The first recess RS1 may be formed between adjacent sacrificial patterns PP. A width in the second direction D2 of the first recess RS1 may become smaller in a direction approaching the substrate 100.

The sacrificial layers SAL may be exposed by the first recess RS1. A process of selectively etching the exposed sacrificial layers SAL may be performed. The etching process may include a wet etching process of selectively removing only silicon-germanium. An indent region IDR may be formed by indenting each of the sacrificial layers SAL in the etching process. A sidewall of the sacrificial layer SAL may become concave due to the indent region IDR. An insulating layer that fills the indent regions IDR may be formed in the first recess RS1. The first to third semiconductor patterns SP1, SP2, and SP3 and the sacrificial layers SAL exposed by the first recess RS1 may be seed layers of the insulating layer. The insulating layer may be grown as a crystalline dielectric layer on a crystalline semiconductor that constitutes the first to third semiconductor patterns SP1, SP2, and SP3 and the sacrificial layers SAL.

An inner spacer ISP that fills the indent region IDR may be formed. Specifically, forming the inner spacer ISP may include wet-etching an epitaxial dielectric layer until sidewalls of the first to third semiconductor patterns SP1, SP2, and SP3 are exposed. Accordingly, the epitaxial dielectric layer may remain only in the indent region IDR to constitute the inner spacer ISP.

Referring back to FIGS. 9A to 9C, the second recesses RS2 in the stack pattern STP on the second active pattern AP2 may be formed in a process similar to forming the first recesses RS1. Indent regions IDE may be formed on the second active pattern AP2 by performing a process of selectively etching the sacrificial layers SAL exposed by the second recess RS2. The second recess RS2 may have an inner sidewall having a wavy or uneven shape due to the indent regions IDE. The inner spacer ISP may not be formed in the indent regions IDE on the second active pattern AP2. The first to third semiconductor patterns SP1, SP2, and SP3 between the second recesses RS2 adjacent to each other may constitute the second channel pattern CH2.

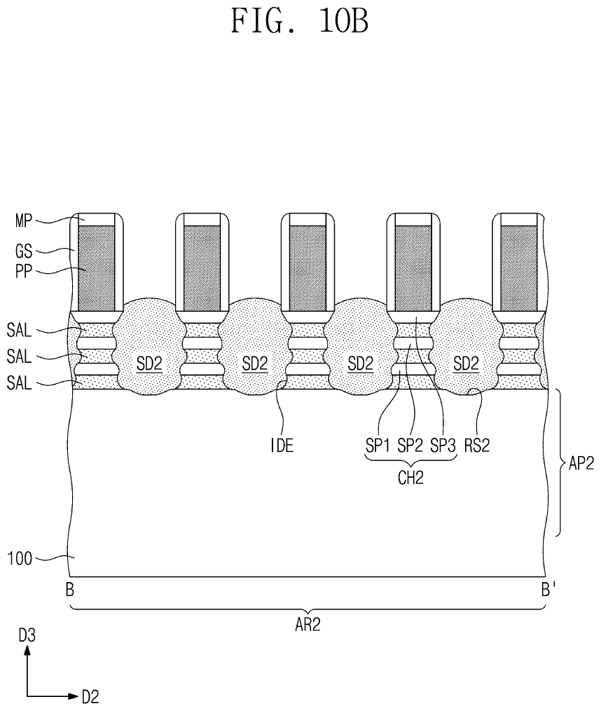

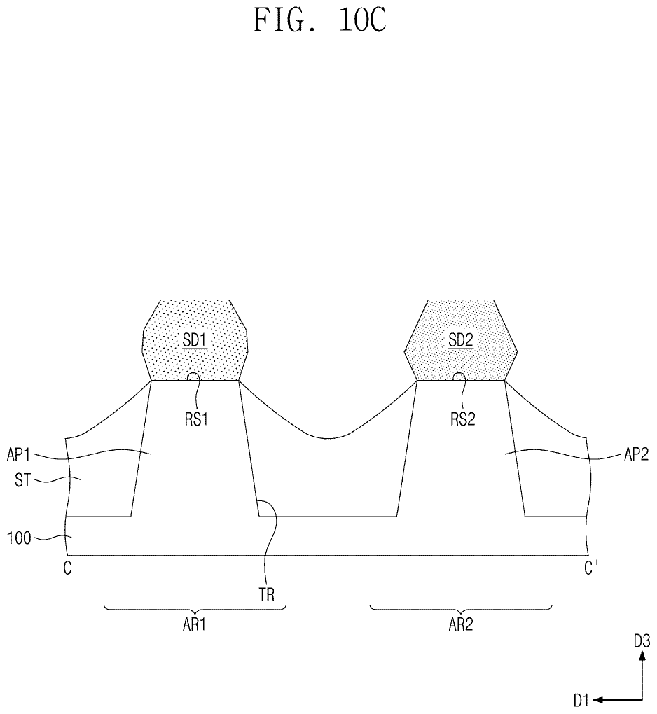

Referring to FIGS. 10A to 10C, the first source/drain patterns SD1 may be respectively formed in the first recesses RS1. Specifically, an epitaxial layer that fills the first recess RS1 may be formed by performing a SEG process using an inner sidewall of the first recess RS1 as a seed layer. The epitaxial layer may be grown using the first to third semiconductor patterns SP1, SP2, and SP3 and the substrate 100 exposed by the first recess RS1 as seed layers. For example, the SEG process may include a chemical vapor deposition (CVD) process or a molecular beam epitaxy (MBE) process.

According to an embodiment of the inventive concept, the first source/drain pattern SD1 may include the same semiconductor element (for example, Si) as the substrate 100. During forming the first source/drain pattern SD1, an impurity (for example, phosphorous, arsenic or antimony) that causes the first source/drain pattern SD1 to have an N-type may be in-situ injected. For another example, after forming the first source/drain pattern SD1, the impurity may be injected into the first source/drain pattern SD1.

The second source/drain patterns SD2 may be respectively formed in the second recesses RS2. Specifically, the second source/drain pattern SD2 may be formed by performing a SEG process using an inner sidewall of the first to third semiconductor patterns SP1, SP2, and SP3 exposed by the second recess RS2 as a seed layer.

According to an embodiment of the inventive concept, the second source/drain pattern SD2 may include a semiconductor element (for example, SiGe) having a greater lattice parameter than a semiconductor element of the substrate 100. During forming the second source/drain pattern SD2, an impurity (for example, boron, gallium, or indium) that causes the second source/drain pattern SD2 to have a P-type may be in-situ injected. For another example, after forming the second source/drain pattern SD2, the impurity may be injected into the second source/drain pattern SD2.

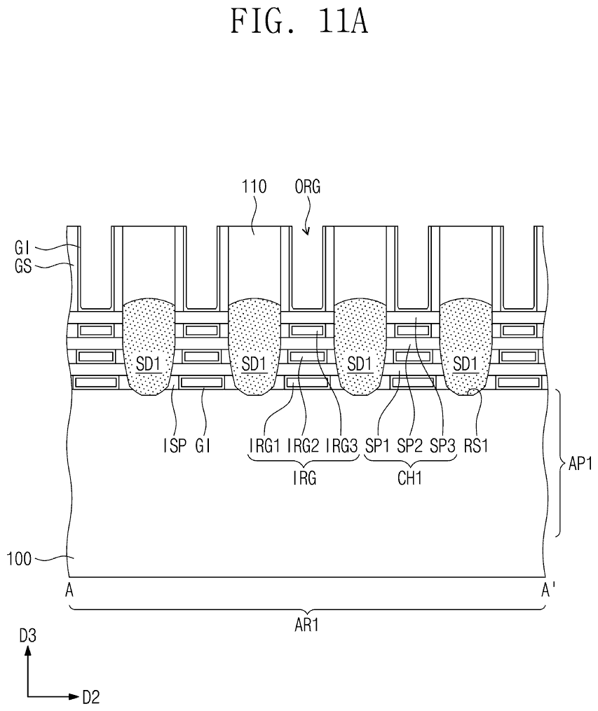

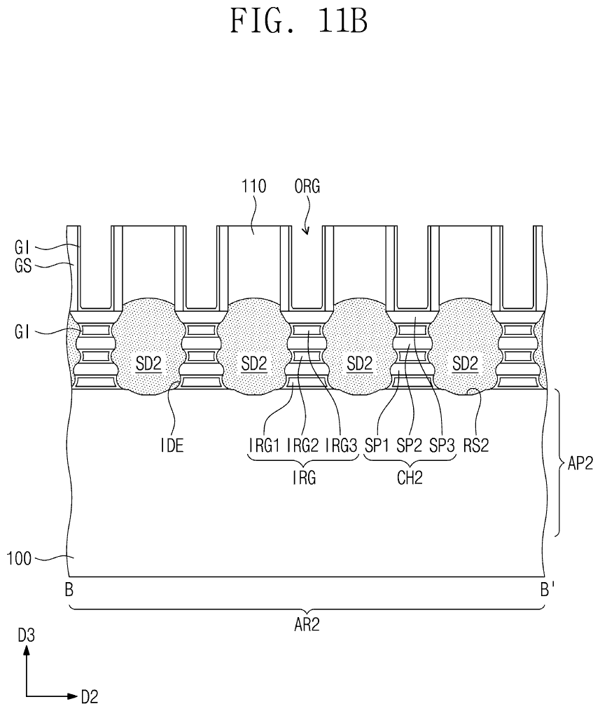

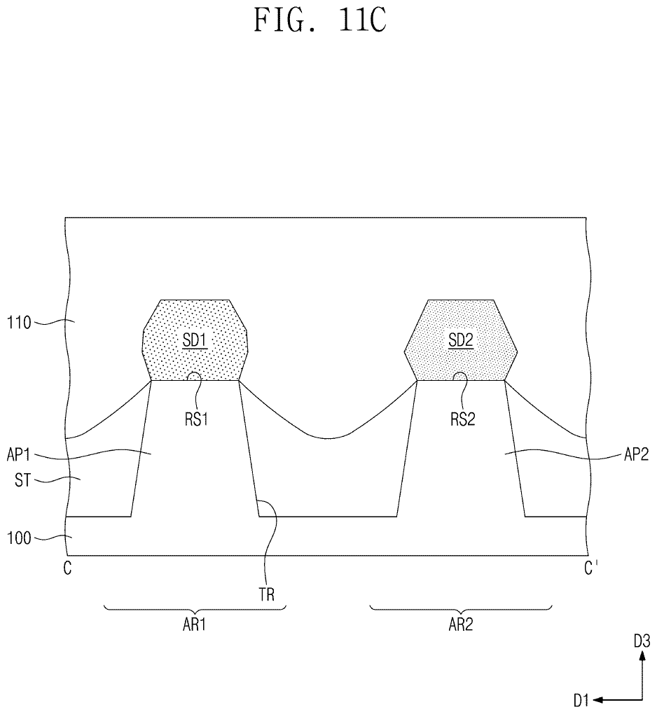

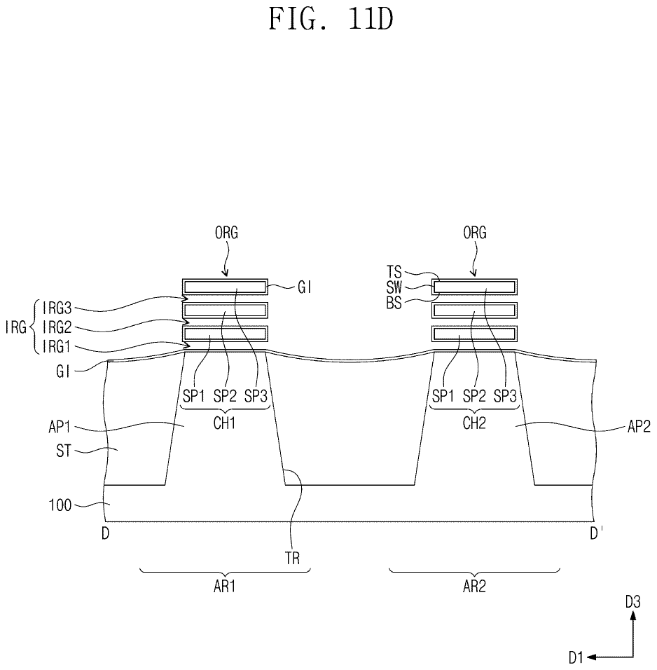

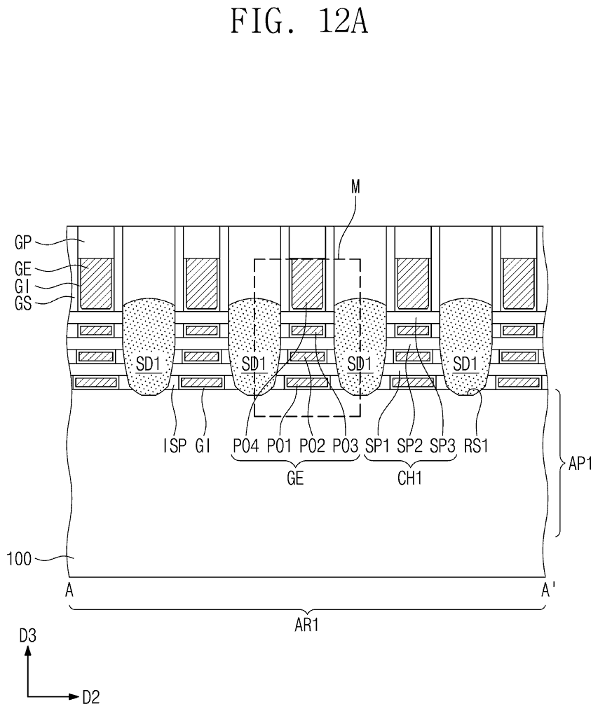

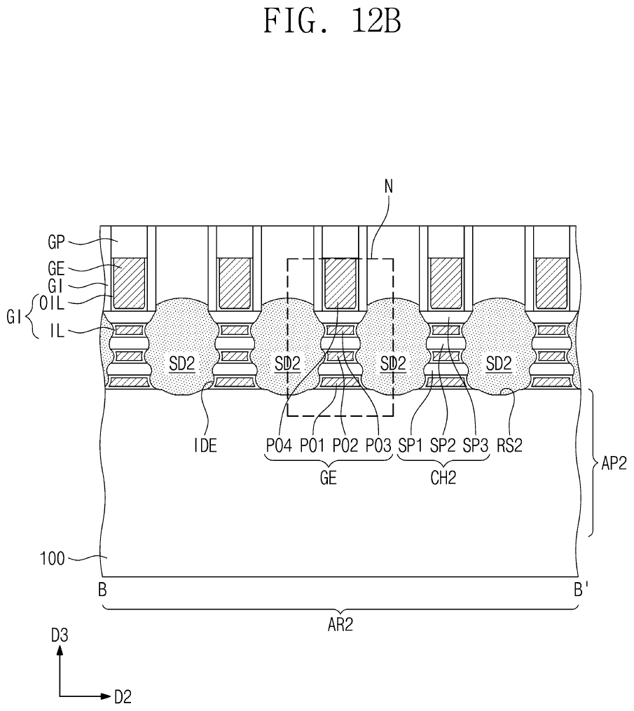

Referring to FIGS. 11A to 11D, the first interlayered insulating layer 110 covering the first and second source/drain patterns SD1 and SD2, the hard-mask patterns MP and the gate spacers GS may be formed. For example, the first interlayered insulating layer 110 may include a silicon oxide layer.

The first interlayered insulating layer 110 may be planarized until top surfaces of the sacrificial patterns PP are exposed. The first interlayered insulating layer 110 may be planarized by using an etch-back process or a chemical mechanical polishing (CMP) process. During the planarization process, the hard-mask patterns MP may be all removed. As a result, a top surface of the first interlayered insulating layer 110 may be coplanar with top surfaces of the sacrificial patterns PP and top surfaces of the gate spacers GS.

The exposed sacrificial patterns PP may be selectively removed. The outer region ORG exposing the first and second channel patterns CH1 and CH2 may be formed by removing the sacrificial patterns PP (see FIG. 11D). Removing the sacrificial patterns PP may include wet etching using an etchant that selectively etches polysilicon.

The inner regions IRG may be formed by selectively removing the sacrificial layers SAL exposed through the outer region ORG (see FIG. 11D). Specifically, the first to third semiconductor patterns SP1, SP2, and SP3 may remain and only the sacrificial layers SAL may be removed by performing a process of selectively etching the sacrificial layers SAL. The etching process may have a high etch-rate for silicon-germanium having a relatively high germanium concentration. For example, the etching process may have a high etch-rate for silicon-germanium having a greater germanium concentration than about 10 at %.

The sacrificial layers SAL on the first and second active regions AR1 and AR2 may be removed during the etching process. The etching process may be wet etching. An etchant used in the etching process may rapidly remove the sacrificial layer SAL having a relatively high germanium concentration.

Referring back to FIG. 11D, the sacrificial layers SAL may be selectively removed so that only the stacked first to third semiconductor patterns SP1, SP2, and SP3 may remain on each of the first and second active patterns AP1 and AP2. The first to third inner regions IRG1, IRG2, and IRG3 may be respectively formed through regions in which the sacrificial layers SAL are removed.

Specifically, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring back to FIGS. 11A to 11D, the gate insulating layer GI may be formed on the exposed first to third semiconductor patterns SP1, SP2, and SP3. The gate insulating layer GI may be formed so as to surround each of the first to third semiconductor patterns SP1, SP2, and SP3. The gate insulating layer GI may be formed in the first to third inner regions IRG1, IRG2, and IRG3. The gate insulating layer GI may be formed in the outer region ORG.

Referring to FIGS. 12A to 12D, the gate electrode GE may be formed on the gate insulating layer GI. The gate electrode GE may include the first to third parts PO1, PO2, and PO3 respectively formed in the first to third inner regions IRG1, IRG2, and IRG3 and the fourth part PO4 formed in the outer region ORG. The gate electrode GE may be recessed to reduce a height thereof. The gate capping pattern GP may be formed on the recessed gate electrode GE.

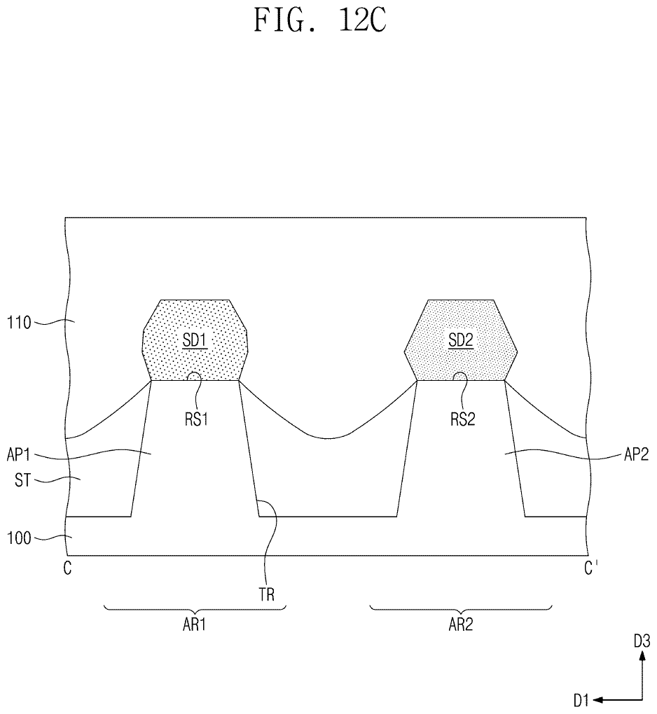

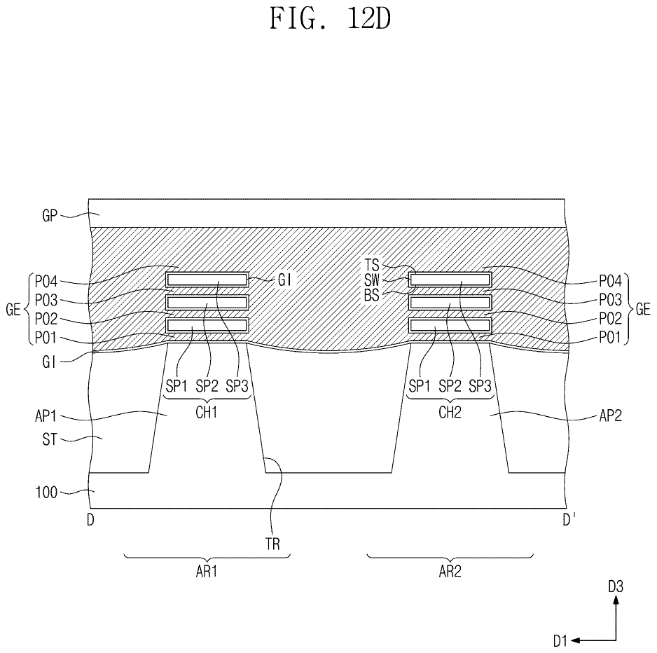

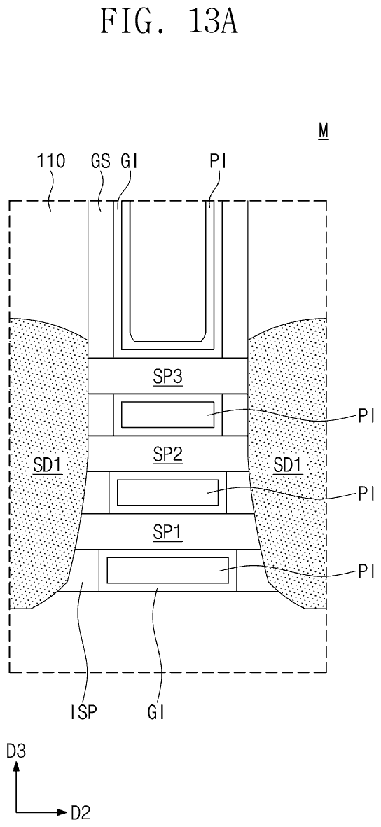

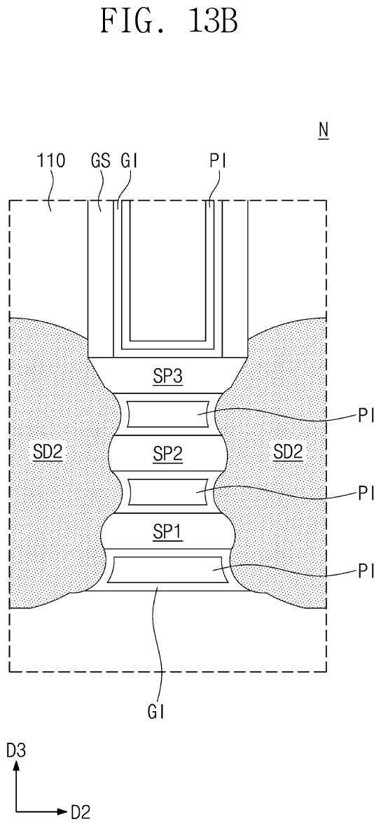

FIGS. 13A to 18B are enlarged diagrams, for describing a method for forming an outer electrode of the gate electrodes, illustrating region M of FIG. 5A and region N of FIG. 5B. The method for manufacturing the gate electrode GE formed in FIGS. 12A to 12B will be described in more detail.

Referring to FIGS. 13A and 13B, a preliminary metal oxide layer PI may be formed on the outer region ORG and the first to third inner regions IRG1, IRG2, and IRG3 of each of the first active pattern AP1 and the second active pattern AP2. The preliminary metal oxide layer PI may be formed by performing a deposition process on the gate insulating layer GI. For example, the preliminary metal oxide layer PI may include aluminum oxide (AlO). Specifically, the preliminary metal oxide layer PI may completely fill each of the first to third inner regions IRG1, IRG2, and IRG3, and may be formed with a substantially uniform thickness on the outer region ORG.

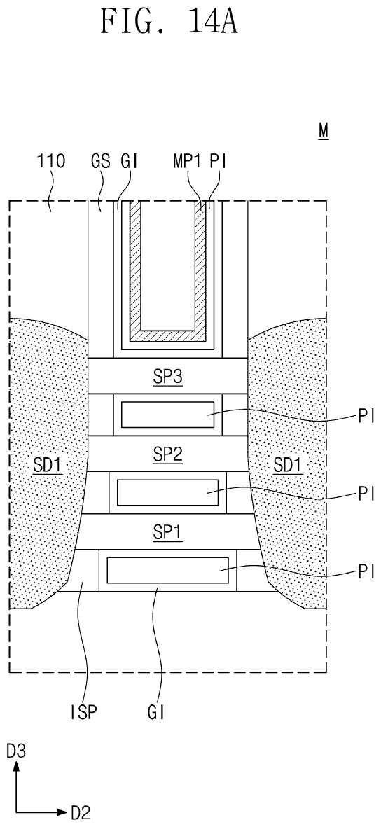

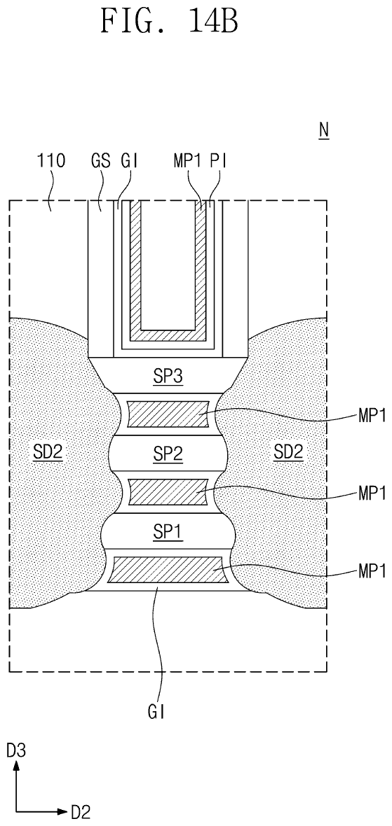

Referring to FIGS. 14A and 14B, a mask layer may be formed on an NMOSFET region (for example, the first region AR1) including the first active pattern AP1 to open a PMOSFET region (for example, the second active region AR2) including the second active pattern AP2. The preliminary metal oxide layer PI on the PMOSFET region may be all removed by performing wet-etching or dry-etching on the PMOSFET region. That is, the first to third inner regions IRG1, IRG2, and IRG3 and the outer region ORG may be formed on the PMOSFET region again.

The first metal pattern MP1 may be formed so as to fill the first to third inner regions IRG1, IRG2, and IRG3 and the outer region ORG re-formed after removing the mask layer formed on the NMOSFET region. The first metal pattern MP1 may be simultaneously formed on the PMOSFET region and on the preliminary metal oxide layer PI on the NMOSFET region. That is, the gate insulating layer GI, the preliminary metal oxide layer PI and the first metal pattern MP1 may be sequentially stacked on an uppermost third semiconductor pattern SP3 on the NMOSFET region.

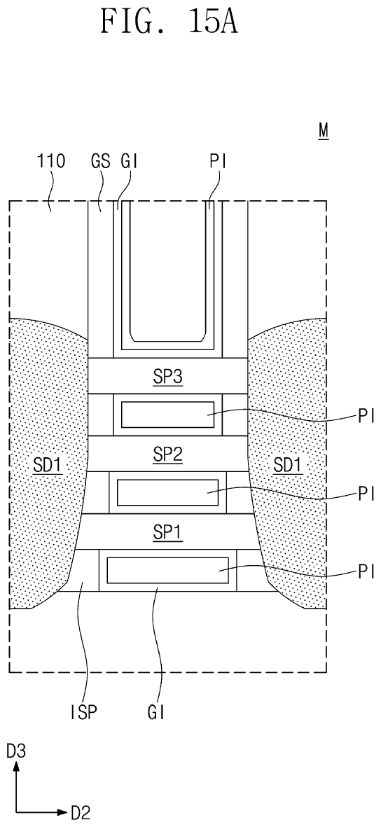

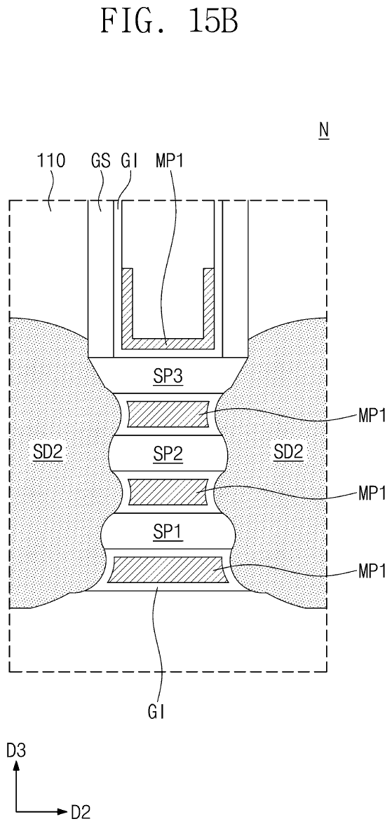

Referring to FIGS. 15A and 15B, the first metal pattern MP1 may be partially or entirely removed by performing a process of etching the first metal pattern MP1 on each of the PMOSFET region and the NMOSFET region. The etching process may be a wet-etching process or a dry-etching process. For another example, the etching process may be an etch-back process.

Specifically, the first metal pattern MP1 on the NMOSFET region may be all removed after performing the etching process. That is, only the preliminary metal oxide layer PI may remain on the NMOSFET region. The first metal pattern MP1 on the PMOSFET region may be partially removed after performing the etching process. An upper portion of the first metal pattern MP1 on the PMOSFET region may be partially removed so that the first metal pattern MP1 may have a U shape on or in a cross-sectional view.

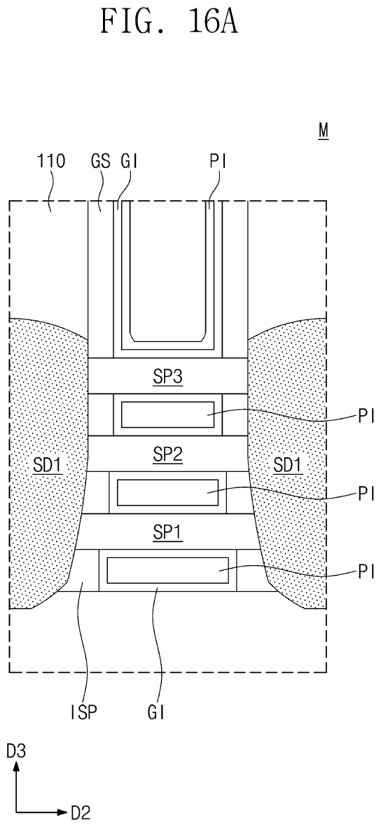

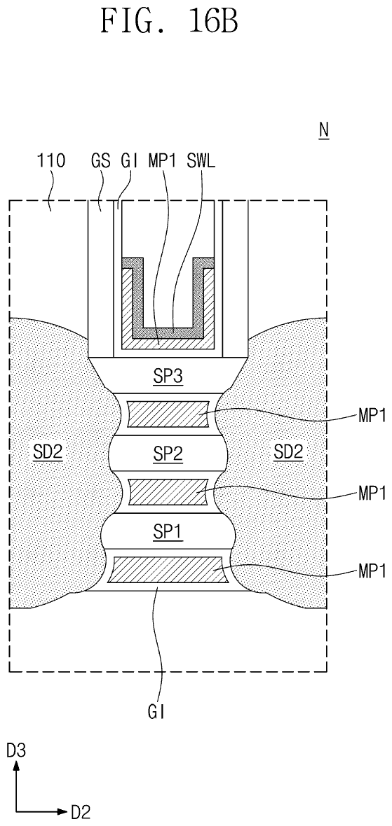

Referring to FIGS. 16A and 16B, the metal liner pattern SWL may be selectively formed only on the PMOSFET region. The metal liner pattern SWL may be formed by performing a deposition process (CVD, PVD or ALD). For example, the metal liner pattern SWL may be formed by performing a selective W (tungsten) CVD process in which tungsten is grown on a metal surface. That is, since a surface of the first metal pattern MP1 on the PMOSFET exposed through the outer region includes a metal material, the metal liner pattern SWL may be formed only on the first metal pattern MP1 on the PMOSFET region. The metal liner pattern SWL may not be formed on the preliminary metal oxide layer PI on the NMOSFET region. According to the present embodiment, the metal liner pattern SWL may include a tungsten (W) material having a relatively low resistance.

The metal liner pattern SWL may be formed in a form of a liner having a substantially uniform thickness. For another example, the metal liner pattern SWL may be formed having a different thickness on the first metal pattern MP1. That is, the metal liner pattern SWL may be formed on a top surface of the first metal pattern MP1 with a relatively small thickness, and may be formed on an inner side surface of the first metal pattern MP1 with a relatively greater thickness.

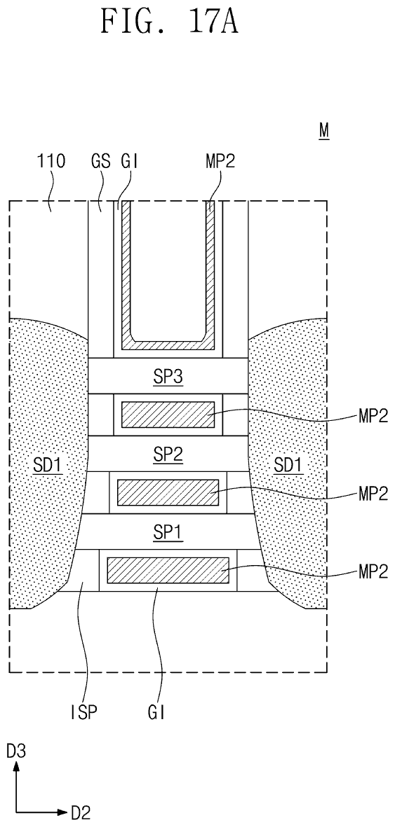

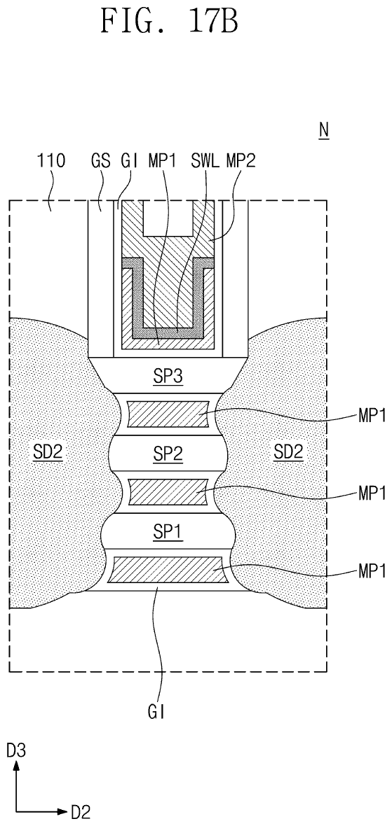

Referring to FIGS. 17A and 17B, the mask layer may be formed on the PMOSFET region (for example, the second active region AR2) including the second active pattern AP2 to open the NMOSFET region (for example, the first active region AR1) including the first active pattern AP1. The preliminary metal oxide layer PI may be all removed on the NMOSFET region by performing wet-etching or dry-etching on the NMOSFET region. That is, the first to third inner regions IRG1, IRG2, and IRG3 and the outer region ORG may be formed on the NMOSFET region again.

The second metal pattern MP2 may be formed so as to fill the first to third inner regions IRG1, IRG2, and IRG3 and the outer region ORG re-formed after removing the mask layer formed on the PMOSFET region. The second metal pattern MP2 may be simultaneously formed on the NMOSFET region, and on the metal liner pattern SWL on the PMOSFET region. That is, the gate insulating layer GI, the first metal pattern MP1, the metal liner pattern SWL and the second metal pattern MP2 may be sequentially stacked on the uppermost third semiconductor pattern SP3 on the PMOSFET region.

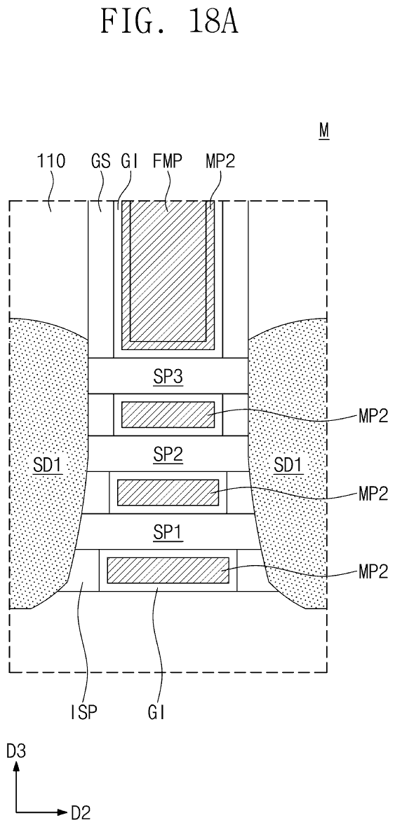

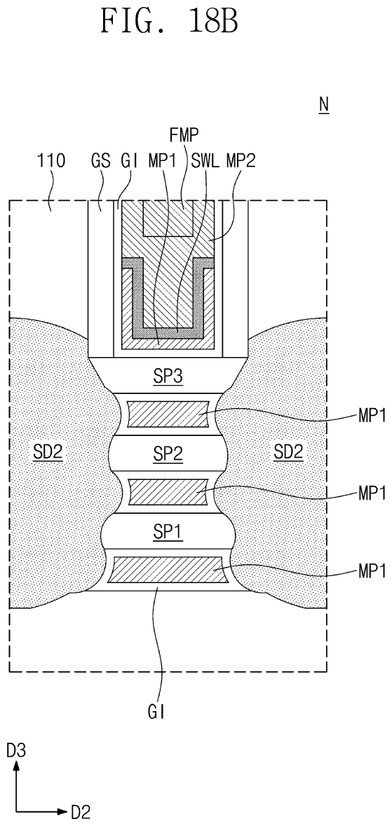

When the metal liner pattern SWL has a form of a liner having a substantially uniform thickness, the first metal pattern MP1 and the second metal pattern MP2 on the PMOSFET region may be spaced apart from each other with the substantially uniform thickness. In other words, portions of the first metal pattern MP1 may be separated from portions of the second metal pattern MP2 by a substantially uniform distance (corresponding to the thickness of the metal liner pattern SWL. For another example, when the metal liner pattern SWL is formed having various thicknesses on the first metal pattern MP1, distances between the first metal pattern MP1 and the second metal pattern MP2 on the PMOSFET region may be various or varied. That is, according to the manufacturing method according to the inventive concept, a distance between the first metal pattern MP1 and the second metal pattern MP2 may be controlled by forming the metal liner pattern SWL on the PMOSFET region. Accordingly, a threshold voltage of a PFET may be reduced, and thus electrical characteristics of the semiconductor device may be improved. Referring to FIGS. 18A and 18B, the filling metal pattern FMP may be formed so as to fill an empty space on each of the PMOSFET region and the NMOSFET region. The first outer electrode OGE1 and the second outer electrode OGE2 described above may be formed by forming the filling metal pattern FMP.

Comparing and referring to FIGS. 6C and 18B, according to another embodiment of the inventive concept, the metal filling layer SWFP on the first metal pattern MP1 on the PMOSFET region may fill an empty space. The second outer electrode OGE2 described above may be formed by forming the metal filling layer SWFP.

Referring back to FIGS. 5A to 5D, the second interlayered insulating layer 120 may be formed on the first interlayered insulating layer 110. The second interlayered insulating layer 120 may include a silicon oxide layer. The active contacts AC penetrating the first interlayered insulating layer 110 and the second interlayered insulating layer 120 to be electrically connected to the first and second source/drain patterns SD1 and SD2 may be formed. The gate contact GC penetrating the second interlayered insulating layer 120 and the gate capping pattern GP to be electrically connected to the gate electrode GE may be formed.

Forming each of the active contact AC and the gate contact GC may include forming a barrier pattern BM and forming a conductive pattern FM on the barrier pattern BM. The barrier pattern BM may be conformally formed, and may include a metal layer/metal nitride layer. The conductive pattern FM may include low-resistive metal.

The separation structures DB may be respectively formed on the first boundary BD1 and the second boundary BD2 of the single height cell SHC. The separation structure DB may extend from the second interlayered insulating layer 120 through the gate electrode GE to the inside of the first and second active patterns AP1 and AP2. The separation structure DB may include an insulating material such as a silicon oxide layer or a silicon nitride layer.

The third interlayered insulating layer 130 may be formed on the active contacts AC and the gate contacts GC. The first metal layer M1 may be formed in the third interlayered insulating layer 130. The fourth interlayered insulating layer 140 may be formed on the third interlayered insulating layer 130. The second metal layer M2 may be formed in the fourth interlayered insulating layer 140.

In a semiconductor device according to the inventive concept, transistors having different threshold voltages may be realized by changing a composition (or effective work function) of work function metal that fills an outer electrode among gate electrodes on a PMOSFET region. In addition, a threshold voltage of a PFET and a resistance of the transistor may be lowered by changing the composition of the work function metal that fills the outer electrode on the PMOSFET region, and selectively forming tungsten (W) having a relatively low-resistance. Meanwhile, since the tungsten (W) is selectively formed in an outer region outside an inner region, difficulty in a process of manufacturing a device may be reduced, and reliability of the device may be improved.

Although the embodiments of the present invention have been described, it is understood that the present invention should not be limited to these embodiments but various changes and modifications can be made by one ordinary skilled in the art within the scope of the present invention as hereinafter claimed.

What is claimed is:

1. A semiconductor device comprising:
a substrate comprising an active pattern;
a channel pattern on the active pattern, wherein the channel pattern comprises a plurality of semiconductor patterns that are stacked and spaced apart from each other;
a source/drain pattern connected to the plurality of semiconductor patterns; and
a gate electrode on the plurality of semiconductor patterns, wherein the gate electrode includes respective parts between adjacent semiconductor patterns among the plurality of semiconductor patterns, and an uppermost part on an uppermost semiconductor pattern among the plurality of semiconductor patterns,
wherein the uppermost part comprises:
a first metal pattern;
a second metal pattern on the first metal pattern;
a filling metal pattern on the second metal pattern; and
a metal liner pattern between the first metal pattern and the second metal pattern, and
wherein the metal liner pattern comprises at least one selected from the group consisting of titanium (Ti), tantalum (Ta), niobium (Nb), aluminum (Al), tungsten (W), and molybdenum (Mo).

2. The semiconductor device of claim 1, wherein the metal liner pattern comprises tungsten (W), and has a substantially uniform thickness.

3. The semiconductor device of claim 1, further comprising:
a gate insulating layer between the gate electrode and the adjacent semiconductor patterns,
wherein the first metal pattern is on the gate insulating layer.

4. The semiconductor device of claim 3, wherein the first metal pattern extends around the gate insulating layer in a cross-sectional view.

5. The semiconductor device of claim 3, wherein the first metal pattern has a U shape in a cross-sectional view.

6. The semiconductor device of claim 3, wherein the metal liner pattern extends from a top surface of the first metal pattern onto an inner side surface of the first metal pattern in a cross-sectional view.

7. The semiconductor device of claim 1, wherein a work function of the first metal pattern is different from a work function of the second metal pattern.

8. The semiconductor device of claim 1, wherein the first metal pattern and the second metal pattern are spaced apart from each other by the metal liner pattern.

9. The semiconductor device of claim 1, wherein the first metal pattern has a first thickness that is substantially uniform, and
the metal liner pattern has a second thickness that is substantially uniform.

10. The semiconductor device of claim 9, wherein the first thickness is the same as the second thickness.

11. The semiconductor device of claim 9, wherein the first thickness is greater than the second thickness.

12. The semiconductor device of claim 9, wherein the respective parts of the gate electrode comprise first, second, and third parts that are sequentially stacked, the first part has a third thickness, the second part has a fourth thickness, the third part has a fifth thickness, and the third, fourth, and fifth thicknesses are each greater than the first thickness and the second thickness.

13. A semiconductor device comprising:
a substrate comprising a PMOSFET region;
an active pattern on the PMOSFET region;
a channel pattern on the active pattern and comprising a plurality of semiconductor patterns that are stacked and spaced apart from each other;
a source/drain pattern connected to the plurality of semiconductor patterns;
a gate electrode on the plurality of semiconductor patterns and including respective inner electrodes between adjacent semiconductor patterns among the plurality of semiconductor patterns, and an outer electrode on an uppermost semiconductor pattern among the plurality of semiconductor patterns;
a gate insulating layer between the gate electrode and the adjacent semiconductor patterns; and
an active contact electrically connected to the source/drain pattern,
wherein the outer electrode comprises a first metal pattern and a metal filling layer on the first metal pattern, and
the metal filling layer extends between inner sidewalls of the gate insulating layer and between inner sidewalls of the first metal pattern.

14. The semiconductor device of claim 13, wherein the metal filling layer comprises at least one selected from the group consisting of titanium (Ti), tantalum (Ta), niobium (Nb), aluminum (Al), tungsten (W), and molybdenum (Mo).

15. The semiconductor device of claim 13, wherein a top surface of the metal filling layer is substantially coplanar with a top surface of the gate insulating layer adjacent to the outer electrode.

16. A semiconductor device comprising:
a first active pattern on a first active region of a substrate, and a second active pattern on a second active region of the substrate;
an element separation layer in a trench between the first and second active patterns;
a first channel pattern on the first active pattern and comprising first semiconductor patterns that are stacked and spaced apart from each other;
a second channel pattern on the second active pattern and comprising second semiconductor patterns that are stacked and spaced apart from each other;
a first gate electrode on the first channel pattern;
a second gate electrode on the second channel pattern;
a first interlayered insulating layer on the first and second gate electrodes;
gate contacts penetrating the first interlayered insulating layer and connected to the first and second gate electrodes;
a second interlayered insulating layer on the first interlayered insulating layer;
a first metal layer in the second interlayered insulating layer, wherein the first metal layer comprises first wires electrically connected to the gate contacts;
a third interlayered insulating layer on the second interlayered insulating layer; and
a second metal layer in the third interlayered insulating layer,
wherein the second metal layer comprises second wires electrically connected to the first wires,
the first gate electrode comprises respective first inner electrodes in inner regions between the first semiconductor patterns, and a first outer electrode on an uppermost first semiconductor pattern among the first semiconductor patterns,
wherein the second gate electrode comprises respective second inner electrodes in inner regions between the second semiconductor patterns, and a second outer electrode on an uppermost second semiconductor pattern among the second semiconductor patterns,
wherein the first outer electrode comprises:
a first metal pattern; and
a filling metal pattern on the first metal pattern,
wherein the second outer electrode comprises:
a second metal pattern;
a third metal pattern on the second metal pattern;
a metal liner pattern between the second and third metal patterns; and
the filling metal pattern on the third metal pattern, and
wherein the metal liner pattern comprises tungsten (W) and has a substantially uniform thickness.

17. The semiconductor device of claim 16, wherein the first outer electrode is free of tungsten (W).

18. The semiconductor device of claim 16, wherein the first metal pattern and the second metal pattern comprise a same metal material, and
the third metal pattern comprises a metal material different from those of the first and second metal patterns.

19. The semiconductor device of claim 16, wherein a work function of the first metal pattern and a work function of the second metal pattern are different from a work function of the third metal pattern.

20. The semiconductor device of claim 16, wherein a resistance value of the second outer electrode is smaller than a resistance value of the first outer electrode.
